(19) United States
(12) Patent Application Publication
(10) Pub. No.: US 2026/0262250 A1
(43) Pub. Date: Sep. 3, 2026

(54) INSULATED GATE SEMICONDUCTOR DEVICE

(71) Applicant: FUJI ELECTRIC CO., LTD., Kawasaki-shi (JP)

(72) Inventor: Keiji OKUMURA, Matsumoto-city (JP)

(73) Assignee: FUJI ELECTRIC CO., LTD., Kawasaki-shi (JP)

(21) Appl. No.: 19/439,083

(22) Filed: Jan. 2, 2026

(30) Foreign Application Priority Data
Feb. 28, 2025 (JP) 2025-032050

(51) Int. Cl. H10D 30/66; H10D 62/10; H10D 62/832

(52) U.S. Cl. CPC H10D 30/668; H10D 62/109; H10D 62/8325

(57) ABSTRACT

An insulated gate semiconductor device includes: a drift layer of a first conductivity-type; a base region of a second conductivity-type provided on a top surface side of the drift layer; a main region of the first conductivity-type provided on a top surface side of the base region; and a gate electrode buried, with a gate insulating film interposed, in trenches dug downward from a top surface of the main region, wherein a plurality of mesa parts interposed between the trenches adjacent to each other are arranged in a matrix form, and a width of the respective mesa parts at least in one direction is set to 600 nanometers or smaller.

### CROSS-REFERENCE TO RELATED APPLICATION

This application claims benefit of priority under 35 USC 119 based on Japanese Patent Application No. 2025-032050 filed on February 28, 2025, the entire contents of which are incorporated by reference herein.

### BACKGROUND OF THE INVENTION

### Field of the Invention

The present disclosure relates to insulated gate semiconductor devices.

### Description of the Related Art

JP6631632B2 discloses a MOSFET (SiC-MOSFET) including silicon carbide having a matrix-type cell structure in which rectangles are two-dimensionally arranged, and a FinFET structure.

JP7259215B2 discloses a SiC-MOSFET having a matrix-type cell structure.

F. Udrea et al., “Experimental demonstration, challenges, and prospects of the vertical SiC FinFET”, 2022 IEEE 34th ISPSD, May 2022, p. 253-255 discloses a SiC-MOSFET having a FinFET structure.

Conventional insulated gate semiconductor devices are still required to have a configuration capable of reducing ON-resistance.

### SUMMARY OF THE INVENTION

The present disclosure provides an insulated gate semiconductor device having a configuration capable of reducing ON-resistance.

To solve the problems described above, an aspect of the present disclosure inheres in an insulated gate semiconductor device including: a drift layer of a first conductivity-type; a base region of a second conductivity-type provided on a top surface side of the drift layer; a main region of the first conductivity-type provided on a top surface side of the base region; and a gate electrode buried, with a gate insulating film interposed, in trenches dug downward from a top surface of the main region, wherein a plurality of mesa parts interposed between the trenches adjacent to each other are arranged in a matrix form, and a width of the respective mesa parts at least in one direction is set to 0.6 micrometers or smaller.

### BRIEF DESCRIPTION OF THE DRAWINGS

FIG. 1 is a vertical cross-sectional view illustrating an insulated gate semiconductor device according to a first embodiment;

FIG. 2 is a horizontal cross-sectional view as viewed from direction a-a in FIG. 1;

FIG. 3 is a vertical cross-sectional view taken along line B-B' in FIG. 2;

FIG. 4 is a schematic view illustrating a hexagonal crystal system;

FIG. 5 is a schematic view for explaining a plane orientation of side surfaces of trenches;

FIG. 6 is a schematic view for explaining the plane orientation of the side surfaces of the trench;

FIG. 7 is a graph showing a relation between a gate voltage and mobility regarding the plane orientation of the side surfaces of the trench;

FIG. 8 is a horizontal cross-sectional view illustrating an insulated gate semiconductor device of a comparative example;

FIG. 9 is a graph showing a relation between a FIN width and a channel resistance;

FIG. 10 is a horizontal cross-sectional view illustrating an insulated gate semiconductor device according to a second embodiment;

FIG. 11 is a horizontal cross-sectional view illustrating an insulated gate semiconductor device according to a third embodiment;

FIG. 12 is a horizontal cross-sectional view illustrating an insulated gate semiconductor device according to a fourth embodiment;

FIG. 13 is a horizontal cross-sectional view illustrating an insulated gate semiconductor device according to a fifth embodiment;

FIG. 14 is a horizontal cross-sectional view illustrating an insulated gate semiconductor device according to a sixth embodiment;

FIG. 15 is a horizontal cross-sectional view illustrating an insulated gate semiconductor device according to a seventh embodiment;

FIG. 16 is a horizontal cross-sectional view illustrating an insulated gate semiconductor device according to an eighth embodiment;

FIG. 17 is a horizontal cross-sectional view illustrating an insulated gate semiconductor device according to a ninth embodiment;

FIG. 18 is a horizontal cross-sectional view illustrating an insulated gate semiconductor device according to a tenth embodiment;

FIG. 19 is a horizontal cross-sectional view illustrating an insulated gate semiconductor device according to an eleventh embodiment; and

FIG. 20 is a horizontal cross-sectional view illustrating an insulated gate semiconductor device according to a twelfth embodiment.

### DETAILED DESCRIPTION

With reference to the drawings, first to twelfth embodiments of the present disclosure will be described below.

In the drawings, the same or similar elements are indicated by the same or similar reference numerals, and overlapping explanations are not repeated. The drawings are schematic, and it should be noted that the relationship between thickness and planer dimensions, the thickness proportion of each layer, and the like are different from real ones. Moreover, in some drawings, portions are illustrated with different dimensional relationships and proportions. The first to twelfth embodiments described below merely illustrates schematically devices and methods for specifying and giving shapes to the technical idea of the present disclosure, and the span of the technical idea is not limited to materials, shapes, structures, and relative positions of elements described herein.

As used in the present specification, a source region of a metal-oxide-semiconductor field-effect transistor (MOSFET) is referred to as “one of the main regions (a first main region)” that can be used as an emitter region of an insulated gate bipolar transistor (IGBT). The “one of the main regions”, when provided in a thyristor such as a MOS controlled static induction thyristor (SI thyristor), can be used as a cathode region. A drain region of the MOSFET transistor is referred to as the “other one of the main regions (a second main region)” of the semiconductor device that can be used as a collector region in the IGBT or as an anode region in the thyristor. The term “main region”, when simply mentioned in the present specification, is referred to as either the first main region or the second main region that is determined as appropriate by the person skilled in the art.

Further, definitions of directions such as an up-and-down direction in the following description are merely definitions for convenience of understanding, and are not intended to limit the technical ideas of the present disclosure. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction. In addition, a “top surface” may be read as “front surface”, and a “bottom surface” may be read as “back surface”.

Further, in the following description, there is exemplified a case where a first conductivity-type is an n-type and a second conductivity-type is a p-type. However, the relationship of the conductivity types may be inverted to set the first conductivity-type to the p-type and the second conductivity-type to the n-type. Further, a semiconductor region denoted by the symbol “n” or “p” attached with “+” indicates that such semiconductor region has a relatively high impurity concentration or a relatively low specific resistance as compared to a semiconductor region denoted by the symbol “n” or “p” without “+”. A semiconductor region denoted by the symbol “n” or “p” attached with “-” indicates that such semiconductor region has a relatively low impurity concentration or a relatively high specific resistance as compared to a semiconductor region denoted by the symbol “n” or “p” without “-”. However, even when the semiconductor regions are denoted by the same reference symbols “n” and “n”, it is not indicated that the semiconductor regions have exactly the same impurity concentration or the same specific resistance.

Further, the term “common to (the same as)” regarding impurity concentrations, widths, depths, thicknesses, or the like as used herein includes the meanings corresponding to not only a case of strictly “common to (the same as)” but also a margin of error derived from variations in process that can be regarded as substantially “common to (the same as)”. The term “margin of error” refers to a range of plus or minus 10% of the meanings corresponding to the case of strictly “common to (the same as)”, for example.

Further, in the following explanations, the sing “−“ added to Miller indices indicates a bar appended to the following index, and the provision with the sing “−“ in front of the corresponding index refers to a negative index.

### FIRST EMBODIMENT

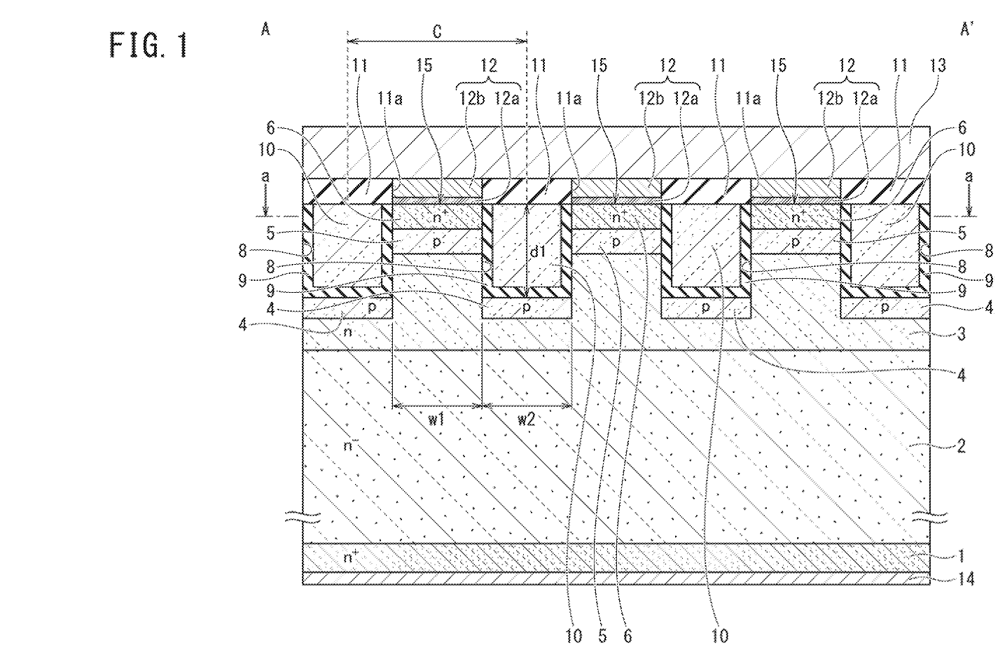

An insulated gate semiconductor device according to a first embodiment is illustrated below with a vertical MOSFET (SiC-MOSFET) including silicon carbide (SiC) having a trench gate structure. SiC as used herein is illustrated with a case of having a structure of a hexagonal crystal system (4H-SiC). While FIG. 1 illustrates the case in which the insulated gate semiconductor device according to the first embodiment includes three unit cells C, the insulated gate semiconductor device may include more than three unit cells C arranged in parallel so as to implement a multi-channel structure.

The insulated gate semiconductor device according to the first embodiment includes a drift layer 2 which is a semiconductor region of a first conductivity-type (n⁻-type) including SiC, as illustrated in FIG. 1. The drift layer 2 has an impurity concentration set in a range of about 1 × 10¹⁵ cm⁻³ or higher and 5 × 10¹⁶ cm⁻³ or lower, for example.

A current spreading layer (CSL) 3 which is a semiconductor region of the first conductivity-type (n-type) having a higher impurity concentration than the drift layer 2 is provided on the top surface side of the drift layer 2. The current spreading layer 3 has an impurity concentration set in a range of about 5 × 10¹⁶ cm⁻³ or higher and 5 × 10¹⁷ cm⁻³ or lower, for example. The provision of the current spreading layer 3 is optional.

A base region 5 which is a semiconductor region of a second conductivity-type (p-type) is provided on the top surface side of the current spreading layer 3 in the respective unit cells C. The base region 5 has an impurity concentration set in a range of about 1 × 10¹⁷ cm⁻³ or higher and 1 × 10¹⁸ cm⁻³ or lower, for example. The bottom surface of the base region 5 may be in contact with the top surface of the drift layer 2 when the current spreading layer 3 is not provided.

A first main region (a source region) 6 which is a semiconductor region of the first conductivity-type (n⁺-type) having a higher impurity concentration than the drift layer 2 is provided on the top surface side of the base region 5 in the respective unit cells C. The source region 6 has an impurity concentration set in a range of about 1 × 10¹⁷ cm⁻³ or higher and 5 × 10¹⁸ cm⁻³ or lower, for example.

Trenches 8 are dug downward (in the depth direction) from the top surface of the source region 6 to penetrate the source region 6 and the base region 5 at the boundaries between the unit cells C adjacent to each other. The respective bottom surfaces of the trenches 8 reach the current spreading layer 3. The side surfaces (side walls) of the trenches 8 are in contact with the source region 6, the base region 5, and the current spreading layer 3. When the current spreading layer 3 is not provided, the bottom surfaces of the trenches 8 reach the drift layer 2, and the side surfaces of the trenches 8 are in contact with the source region 6, the base region 5, and the drift layer 2.

The trenches 8 each have a depth in a range of about 0.7 micrometers or greater and 1.3 micrometers or smaller, and may be about 1 micrometer, for example. While FIG. 1 illustrates the case in which the side surfaces of the trenches 8 are vertical flat surfaces, the respective side surfaces of the trenches 8 may define a tapered shape to make either a trapezoid or an inverted trapezoid in cross section, or may be a curved surface convex outward instead. In addition, FIG. 1 illustrates the case in which the bottom surfaces of the trenches 8 are flat surfaces, but the respective bottom surfaces of the trenches 8 may be a curved surface convex downward. Further, the corners between the bottom surface and the side surfaces of the respective trenches 8 may each have a curvature.

The insulated gate semiconductor device according to the first embodiment includes mesa parts 15 which are each a semiconductor region interposed and defined by the trenches 8 adjacent to each other in the respective unit cells C. The side surfaces of the respective mesa parts 15 correspond to the side surfaces of the respective trenches 8. The respective mesa parts 15 include the source region 6, the base region 5, and the upper part of the current spreading layer 3. The upper part of the current spreading layer 3 is a part interposed between the trenches 8 adjacent to each other. When the current spreading layer 3 is not provided, the respective mesa parts 15 include the source region 6, the base region 5, and the upper part of the drift layer 2. The upper part of the drift layer 2 is a part interposed between the trenches 8 adjacent to each other.

A width W1 of the respective mesa parts 15 conforms to a gap between the respective trenches 8 adjacent to each other. The width W1 of the respective mesa parts 15 may be narrower than, may be common to, or may be greater than a width W2 of the respective trenches 8. The width W2 of the trenches 8 is set in a range of about 200 nanometers or greater and 1 micrometer or smaller. The width W1 of the respective mesa parts 15 is set to about 600 nanometers or smaller, and may be set to about 400 nanometers or smaller, may be set to about 200 nanometers or smaller, or may be set to about 100 nanometers or smaller, for example. The width W1 of the respective mesa parts 15 may also be set in a range of about 50 nanometers or greater and 600 nanometers or smaller, may be set in a range of about 50 nanometers or greater and 400 nanometers or smaller, may be set in a range of about 50 nanometers or greater and 200 nanometers or smaller, or may be set in a range of about 50 nanometers or greater and 100 nanometers or smaller, for example.

A gate insulating film 9 is provided along the bottom and side surfaces of the respective trenches 8. A gate electrode 10 is buried inside the respective trenches 8 with the gate insulating film 9 interposed. The gate insulating film 9 and the gate electrode 10 implement a trench-gate type insulated gate electrode structure (9, 10).

A thickness of the gate insulating film 9 is set in a range of about 30 nanometers or greater and 100 nanometers or smaller, for example. The gate insulating film 9 may be a single-layer film of a silicon oxide (SiO₂) film, a silicon oxynitride (SiON) film, a strontium oxide (SrO) film, a silicon nitride (Si₃N₄) film, an aluminum oxide (Al₂O₃) film, a magnesium oxide (MgO) film, an yttrium oxide (Y₂O₃) film, a hafnium oxide (HfO₂) film, a zirconium oxide (ZrO₂) film, a tantalum oxide (Ta₂O₅) film, or a bismuth oxide (Bi₂O₃) film, or may be a composite film including some of the above films stacked on one another. The gate electrode 10 may be made of a polysilicon layer (a doped polysilicon layer) heavily doped with p-type impurities or n-type impurities, or may include refractory metal, such as titanium (Ti), tungsten (W), and nickel (Ni).

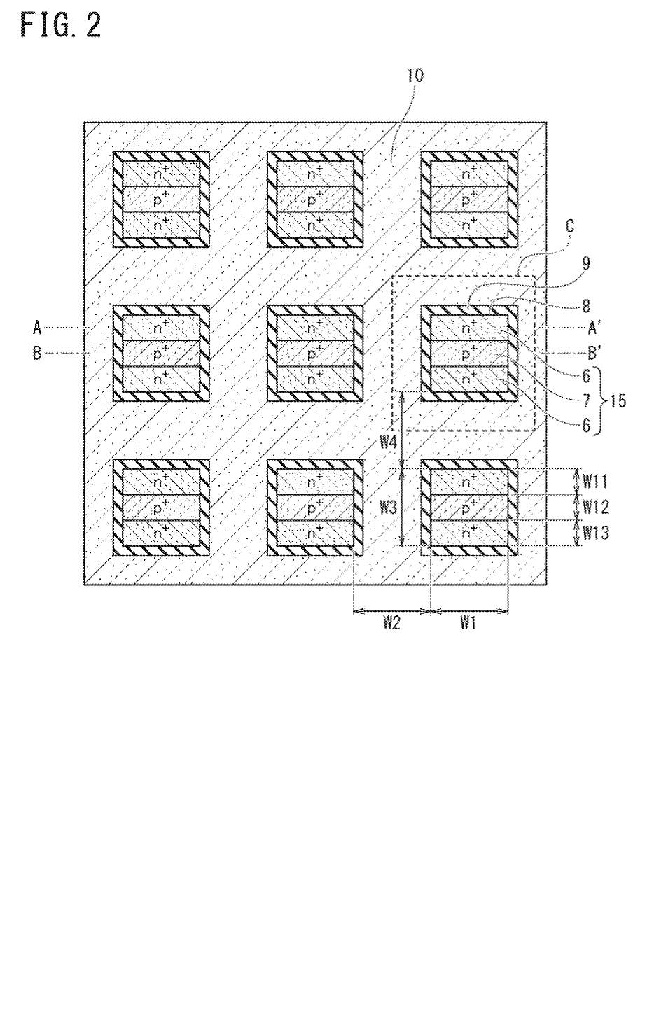

FIG. 2 illustrates a cross section as viewed in the horizontal direction from direction a-a in FIG. 1. FIG. 1 corresponds to the cross section taken along line A-A' in FIG. 2 as viewed in the vertical direction from the lower side to the upper side. As illustrated in FIG. 2, the respective unit cells C have a rectangular planar pattern. The respective trenches 8 have a lattice-like (mesh-like) planar pattern. The trenches 8 each include a plurality of first straight parts (first stripe parts) extending parallel to each other in a first direction which is one direction (the right-left direction in FIG. 2), and a plurality of second straight parts (second stripe parts) extending parallel to each other in a second direction perpendicular to the first direction (the upper-lower direction in FIG. 2) so as to intersect with the plural first straight parts.

As illustrated in FIG. 2, the mesa parts 15 are arranged into a matrix form (a rectangular array) in the first direction (the right-left direction in FIG. 2) and in the second direction (the upper-lower direction in FIG. 2). The present embodiment is illustrated with the configuration in which the entire active region has the common pattern, but does not need to have this configuration. The respective mesa parts 15 may include parts having different patterns, which are only required to be arranged in the first direction and the second direction. The gate insulating film 9 has a frame-shaped planar pattern surrounding the circumference of the respective mesa parts 15. The gate electrode 10 is buried in the respective trenches 8 with the gate insulating film 9 interposed. The gate electrode 10 has a lattice-like (mesh-like) planar pattern, as in the case of the trenches 8. The corners between the side surfaces of the respective trenches 8 may each have a curvature. The side surfaces of the trenches 8 may be curved surfaces convex outward.

A width of the respective mesa parts 15 at least in the one direction is set to 600 nanometers or smaller. The width of the respective mesa parts 15 in the one direction may be narrower than the width of the respective trenches 8 in the one direction. The planar pattern of the respective mesa parts 15 can be any of a polygonal shape, a circular shape, and an elliptic shape. Examples of polygonal shapes include a rectangle (a quadrate) such as a square and an oblong, a triangle, a pentagon, a hexagon, and an octagon. The corners of such a polygonal shape may be rounded off so as to have a curvature. When the respective mesa parts 15 have a polygonal planar pattern, any of the side surfaces of the respective mesa parts 15 may be either an m-plane or an a-plane.

The insulated gate semiconductor device according to the first embodiment is illustrated with the case in which the respective mesa parts 15 have a rectangular, particularly square, planar pattern with a quadrangular prism. A width W3 of the respective mesa parts 15, which have the square planar pattern, in the second direction (the upper-lower direction in FIG. 2) is common to the width W1 of the respective mesa parts 15 in the first direction. When the respective mesa parts 15 have an oblong planar pattern, the width W3 of the respective mesa parts 15 in the second direction (the upper-lower direction in FIG. 2) may be either greater than or narrower than the width W1 of the respective mesa parts 15 in the first direction. A width W4 of the respective trenches 8 between the mesa parts 15 adjacent to each other in the second direction (the upper-lower direction in FIG. 2) may be common to the width W2 of the respective trenches 8 in the first direction (the right-left direction in FIG. 2) between the mesa parts 15 adjacent to each other, or may be either narrower than or greater than the width W2.

The mesa parts 15 each include, in the planar pattern, the two source regions 6 located at both ends in the second direction (the upper-lower direction in FIG. 2), and a base contact region 7 which is a semiconductor region of the second conductivity-type (p⁺-type) interposed between the two source regions 6 so as to be in contact with each other. Widths W11 and W13 of the respective source regions 6 and a width W12 of the base contact region 7 may be either common to or different from each other in the second direction (the upper-lower direction in FIG. 2). The base region 5 hidden under the two source regions 6 and the base contact region 7 has a rectangular (square) planar pattern common to that of the respective mesa parts 15.

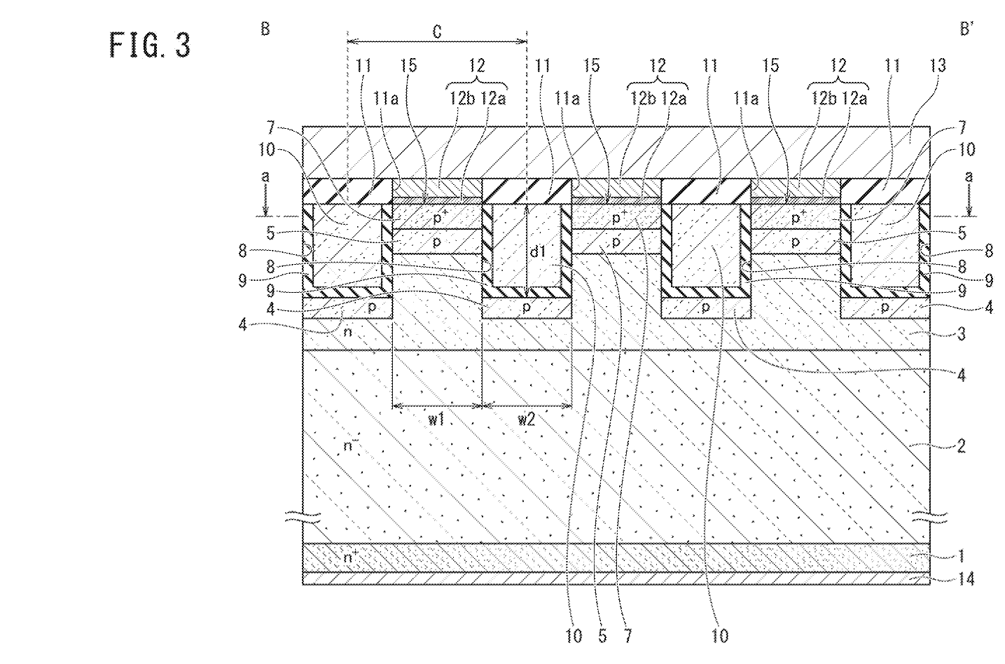

FIG. 3 illustrates a cross section taken along line B-B in FIG. 2 as viewed in the vertical direction from the lower side to the upper side in FIG. 2. As illustrated in FIG. 3, the base contact region 7 is provided on the top surface side of the base region 5 in the respective unit cells C. A depth of the base contact region 7 may be common to the depth of the source region 6 illustrated in FIG. 1, or may be either greater than or shallower than the depth of the source region 6. The bottom surface of the base contact region 7 is in contact with the top surface of the base region 5. The side surfaces of the base contact region 7 are in contact with the respective trenches 8. The base contact region 7 has a greater impurity concentration than the base region 5. The impurity concentration of the base contact region 7 is set in a range of about 5 × 10¹⁹ cm⁻³ or higher and 5 × 10²⁰ cm⁻³ or lower, for example.

The respective mesa parts 15 in the cross section illustrated in FIG. 3 include the base contact region 7, the base region 5, and the upper part of the current spreading layer 3. When the current spreading layer 3 is not provided, the respective mesa parts 15 include the base contact region 7, the base region 5, and the upper part of the drift layer 2.

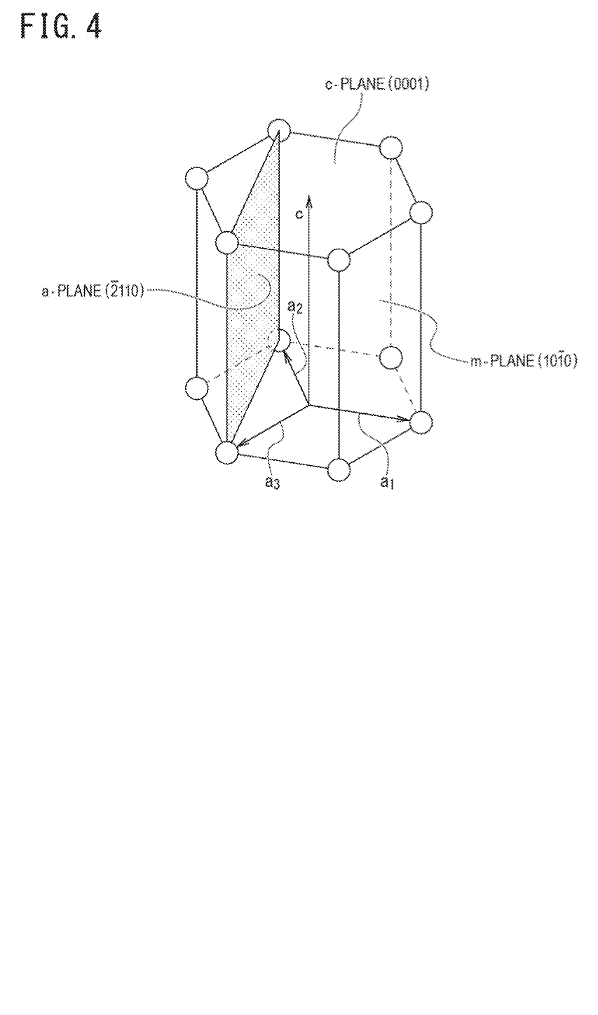

A plane orientation used for the side surfaces of the mesa parts 15 is described below. FIG. 4 is a schematic view illustrating a hexagonal crystal system. The hexagonal crystal system is indicated by coordinate axes including an a₁-axis, an a₂-axis, and an a₃-axis intersecting with each other at an angle of 120 degrees, and a c-axis vertical to the a₁-axis, the a₂-axis, and the a₃-axis and passing through the point of intersection of the a₁-axis, the a₂-axis, and the a₃-axis. The six side surfaces of the hexagonal crystal system parallel to the c-axis are each an m-plane. A plane of the hexagonal crystal system parallel to the a₁-axis, the a₂-axis, and the a₃-axis and vertical to the c-axis is a c-plane. A plane of the hexagonal crystal system parallel to the c-axis and vertical to the a₁-axis is an a-plane.

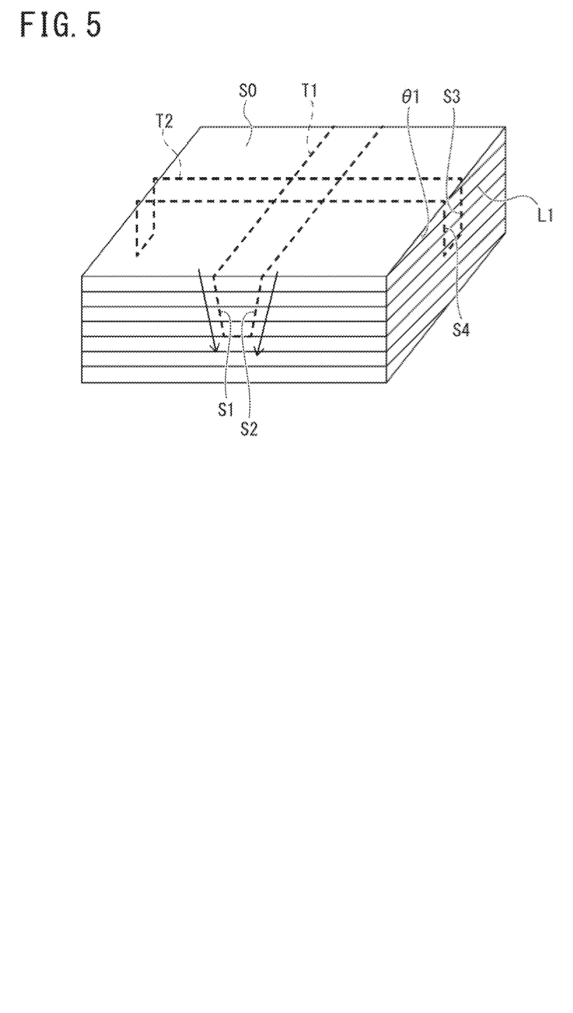

A semiconductor substrate used for the insulated gate semiconductor device according to the first embodiment has an off-angle θ1 in a range of about four to eight degrees in a <11-20> direction with respect to a <0001> (c-axis) direction, for example. The plural straight lines L1 indicated by the solid lines along the side surfaces of the semiconductor substrate illustrated as a rectangular parallelepiped in FIG. 5 schematically show an Si plane. A case is described below in which the semiconductor substrate is provided with a trench T1 and a trench T2 intersecting at right angles with each other. The trench T1 has side surfaces S1 and S2 that are each an m-plane, which is a (1-100) plane orthogonal to a (0001) plane. The side surfaces S1 and S2 of the trench T1 define a tapered shape, and are each an m-plane inclined to the Si plane at about nine degrees.

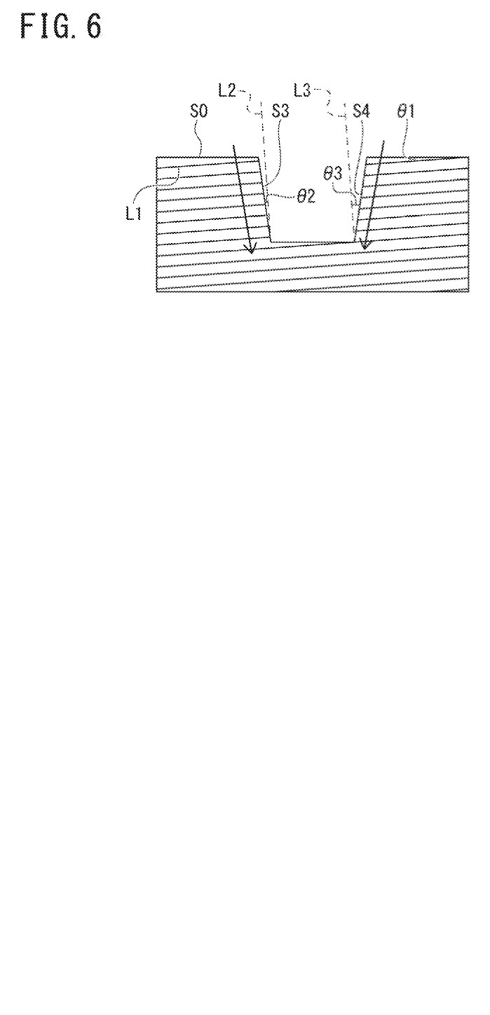

FIG. 6 illustrates the semiconductor substrate provided with the trench T2. As illustrated in FIG. 6, side surfaces S3 and S4 of the trench T2 opposed to each other are each an a-plane which is a (11-20) plane. FIG. 6 schematically indicates broken lines L2 and L3 parallel to the a-plane. Since the semiconductor substrate in this case has the off-angle θ1, an inclined angle θ2 to the a-plane of the side surface S3 on one side of the trench T2 is different from an inclined angle θ3 to the a-plane of the other side surface S4. When the off-angle θ1 is 4 degrees, and a tapered angle of the side surface of the trench T2 is 9 degrees, for example, the side surface S3 of the trench T2 has the inclined angle θ2 on the Si-plane side with respect to the a-plane which is 5 degrees, and the side surface S4 of the trench T2 has the inclined angle θ4 on the Si-plane side with respect to the a-plane which is 13 degrees.

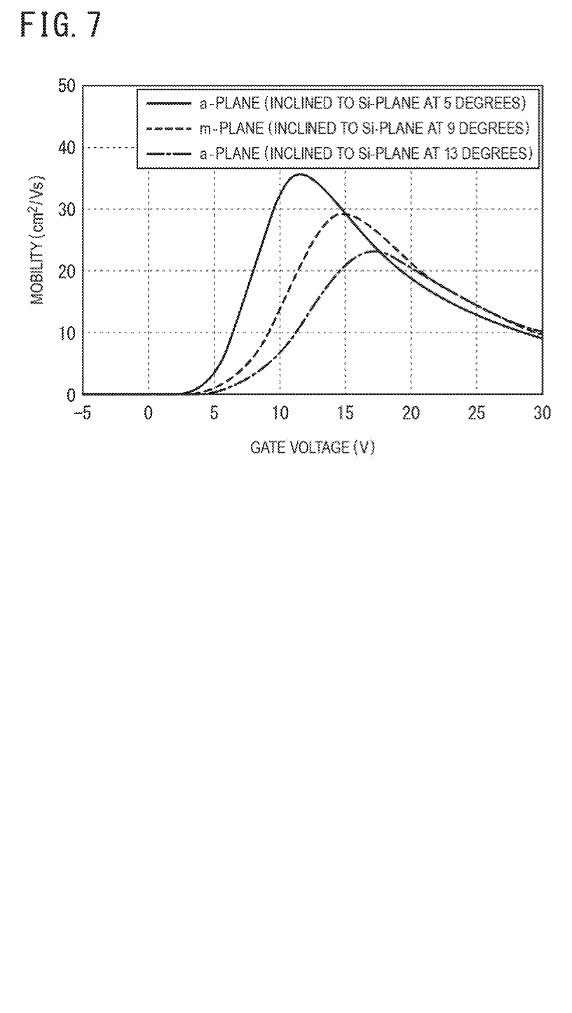

FIG. 7 shows a relation between a gate voltage and mobility of electrons regarding the m-plane inclined to the Si plane at 9 degrees, the a-plane inclined to the Si plane at 5 degrees, and the a-plane inclined to the Si plane at 13 degrees. As shown in FIG. 7, the mobility of electrons is highest on the a-plane inclined to the Si plane at 5 degrees, is second highest on the m-plane inclined to the Si plane at 9 degrees, and is lowest on the a-plane inclined to the Si plane at 13 degrees. This revealed that the mobility of electrons is higher on the one side surface S3 than on the other side surface S4 when the a-plane is used for the side surfaces S3 and S4 opposed to each other in the trench T2.

Any of the four side surfaces orthogonal to the four sides of the square defined by the respective mesa parts 15 in the planar pattern illustrated in FIG. 2 may be either the m-plane or the a-plane. For example, the respective side surfaces in contact with the two sides parallel to the first direction (the right-left direction in FIG. 2) of the respective mesa parts 15 may be defined as the m-plane, and the respective side surfaces in contact with the two sides parallel to the second direction (the upper-lower direction in FIG. 2) of the respective mesa parts 15 may be defined as the a-plane. Namely, the respective mesa parts 15 may have the configuration in which the side surfaces defined only by the source regions 6 are each used as the m-plane, and the side surfaces defined by the source regions 6 and the base contact region 7 are each used as the a-plane so that the base contact region 7 is in contact with the respective a-planes.

As illustrated in FIGS. 1 and 3, a gate-bottom protection region 4 which is a semiconductor region of the second conductivity-type (p⁺-type) is provided inside the current spreading layer 3. The gate-bottom protection region 4 has a function capable of relaxing an electric field applied to the gate insulating film 9 located on the bottom surface of the respective trenches 8. The gate-bottom protection region 4 has an impurity concentration in a range of about 1 × 10¹⁷ cm⁻³ or higher and 1 × 10¹⁹ cm⁻³ or lower, for example. The gate-bottom protection region 4 may be electrically connected to the base region 5 on the either frontward or backward side of the sheet of FIGS. 1 and 3.

While FIGS. 1 and 3 each illustrate the case in which the gate-bottom protection region 4 is in contact with the bottom surfaces of the trenches 8, the gate-bottom protection region 4 may be provided separately from the bottom surfaces of the trenches 8. Further, FIGS. 1 and 3 each illustrate the case in which the gate-bottom protection region 4 has a width common to the width W2 of the respective trenches 8, but the width of the gate-bottom protection region 4 may be either smaller than or greater than the width W2 of the trenches 8. When the current spreading layer 3 is not provided, the gate-bottom protection region 4 may be provided inside the drift layer 2. The provision of the gate-bottom protection region 4 is optional in the present embodiment.

An insulating film 11 which is an interlayer insulating film is provided on the top surface side of the gate electrode 10. The insulating film 11 as used herein can be a single-layer film such as a silicon oxide film (a SiO₂ film) without containing impurities, which is referred to as a non-doped silicate glass (NSG) film, a phosphosilicate glass film (a PSG film) doped with phosphorus, a borosilicate glass film (a BSG film) doped with boron, a borophosphosilicate glass film (a BPSG film) doped with boron and phosphorus, or a silicon nitride film (a Si₃N₄ film), or can be a composite film including some of the above films combined together.

The insulating film 11 is provided with openings (contact holes) 11a on which at least part of the respective top surfaces of the source region 6 and the base contact region 7 are exposed. A contact electrode 12 is buried inside the respective contact holes 11a. The contact electrode 12 is in ohmic contact with the source region 6 and the base contact region 7 at low resistance.

The contact electrode 12 includes a barrier metal layer 12a directly in contact with the respective top surfaces of the source region 6 and the base contact region 7, and a plug layer 12b having a bottom surface in contact with the top surface of the barrier metal layer 12a. The barrier metal layer 12a includes metal such as titanium nitride (TiN) and titanium (Ti), or metal having a stacked structure of TiN/Ti including Ti as a lower layer. The barrier metal layer 12a may be provided so as to cover the insulating film 11. A silicide layer including nickel silicide (NiSiₓ) may be provided between the barrier metal layer 12a and each of the source region 6 and the base contact region 7 so as to ensure an ohmic contact. The plug layer 12b includes metal such as tungsten (W).

A first main electrode (a source electrode) 13 is provided to cover the respective top surfaces of the insulating film 11 and the contact electrode 12. The source electrode 13 is provided separately from a gate wiring layer (not illustrated) electrically connected to the gate electrode 10. The source electrode 13 includes metal such as aluminum (Al) and copper (Cu), or includes a metal alloy such as aluminum-silicon (Al-Si) and aluminum-copper (Al-Cu), for example.

A second main region (a drain region) 1 which is a semiconductor region of the first conductivity-type (n⁺-type) having a higher impurity concentration than the drift layer 2 is provided on the bottom surface side of the drift layer 2. The drain region 1 is a semiconductor substrate (a SiC substrate) including SiC, for example. The impurity concentration of the drain region 1 is set in a range of about 1 × 10¹⁹ cm⁻³ or higher and 3 × 10²⁰ cm⁻³ or lower, for example. Any of a buffer layer, a dislocation conversion layer, and a recombination promotion layer, which are each a semiconductor region of n-type having a higher impurity concentration than the drift layer 2 and having a lower impurity concentration than the drain region 1, may be provided between the drift layer 2 and the drain region 1.

A second main electrode (a drain electrode) 14 is provided on the bottom surface side of the drain region 1. The drain electrode 14 may be a single-layer film including gold (Au) or a metal film including titanium (Ti), nickel (Ni), and Au sequentially stacked together from the drain region 1, and may be further provided with a metal film including molybdenum (Mo) and tungsten (W) as a lowermost layer. A silicide layer including nickel silicide (NiSiₓ) may be provided between the drain region 1 and the drain electrode 14 so as to ensure an ohmic contact.

The insulated gate semiconductor device according to the first embodiment during a switching operation applies a positive voltage to the drain electrode 14 with the source electrode 13 used as an earth potential, and also applies a positive voltage of a threshold or greater to the gate electrode 10. This operation provides inversion layers (channels) in a region of the base region 5 in contact with the gate insulating film 9 in the respective unit cells C so as to lead the vertical MOSFET to be in an ON-state. In the ON-state, a current flows from the drain electrode 14 toward the source electrode 13 through the drain region 1, the drift layer 2, the inversion layers in the base region 5, and the source region 6. When the voltage applied to the gate electrode 10 is less than the threshold, the vertical MOSFET is led to be in an OFF-state while no current flows from the drain electrode 14 toward the source electrode 13, since no inversion layers are formed in the region of the base region 5 in contact with the gate insulating film 9.

The vertical MOSFET implements a FinFET structure in the insulated gate semiconductor device according to the first embodiment. The FinFET structure is referred to as a double-gate structure in which the width W1 of the respective mesa parts 15 interposed between the trenches 8 adjacent to each other is decreased to a predetermined width so as to provide the inversion layers (channels) in the base region 5 interposed between the trenches 8 adjacent to each other. When a gate voltage of the threshold or greater is applied to the gate electrode 10, the FinFET structure applies the voltage between the paired (two) gate electrodes 10 interposing the base region 5 to the entire base region 5.

When the width of the respective mesa parts 15 is 600 nanometers or smaller, the inversion layers are formed in a region (a bulk region) of the base region 5 separated from the interface with the gate insulating film 9 in the respective unit cells C, which is called a “FinFET effect”. This effect can effectively avoid an influence of an interface trap density on electrons moving inside the inversion layers at the interface between the gate insulating film 9 and the base region 5, so as to enhance the mobility of electrons and reduce ON-resistance. The FinFET effect is effective particularly in the insulated gate semiconductor device using SiC, since the mobility of electrons tends to be influenced by the interface trap density that is particularly higher in SiC, which is a compound, than in Si by about one digit. The FinFET effect is increased as the width of the respective mesa parts 15 is decreased. The lower limit of the width of the respective mesa parts 15 is about 50 nanometers, for example, but may be determined as appropriate.

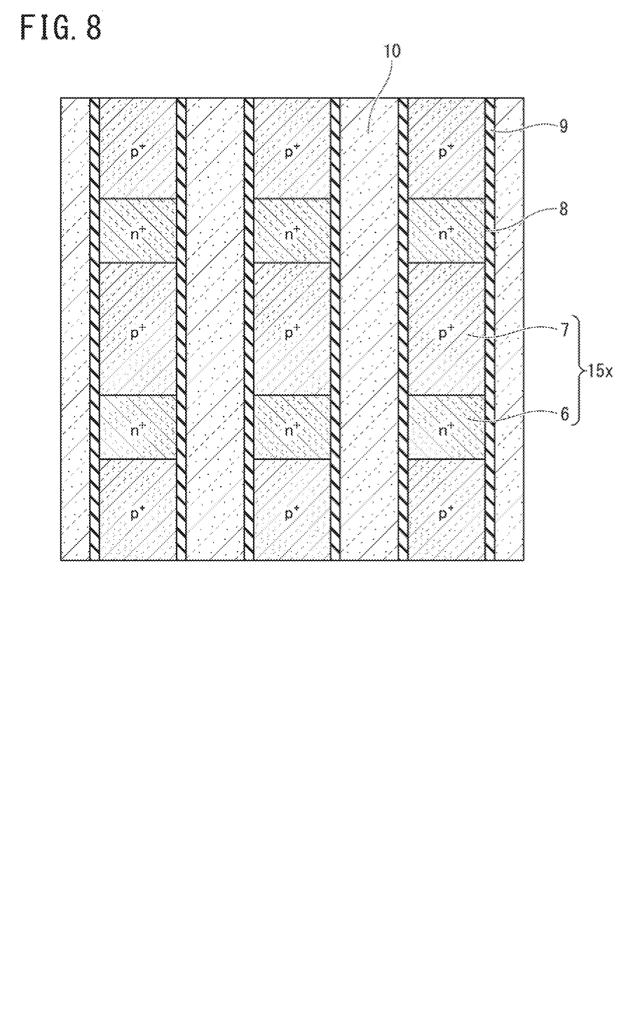

An insulated gate semiconductor device of a comparative example is described below. FIG. 8 illustrates a horizontal cross section in the insulated gate semiconductor device of the comparative example, corresponding to the horizontal cross section of the insulated gate semiconductor device according to the first embodiment illustrated in FIG. 2. As illustrated in FIG. 8, the insulated gate semiconductor device of the comparative example includes the trenches 8 that have a straight (stripe-shaped) planar pattern extending parallel to each other in one direction (the upper-lower direction in FIG. 8). The mesa parts 15x each have a straight (stripe-shaped) planar pattern extending parallel to the extending direction of the trenches 8. The respective mesa parts 15x include the n⁺-type source region 6 and the p⁺-type base contact region 7 that are alternately and repeatedly arranged in the extending direction of the respective trenches 8.

The insulated gate semiconductor device of the comparative example cannot ensure the FinFET effect, except for the paired side surfaces of the respective mesa parts 15x in the direction perpendicular to the extending direction of the respective trenches 8 (in the right-left direction in FIG. 8), regardless of whether the width of the respective mesa parts 15x is decreased in the direction perpendicular to the extending direction of the respective trenches 8, since the mesa parts 15x have the straight (stripe-shaped) planar pattern. In contrast, the insulated gate semiconductor device according to the first embodiment has the configuration in which the respective mesa parts 15 are arranged into a matrix form, and the widths W1 and W2 of the rectangle of the respective mesa parts 15 in the planar pattern are decreased to 600 nanometers or smaller, as illustrated in FIG. 2. This configuration can ensure the FinFET effect on the side surfaces in contact with the respective sides of the rectangle of the respective mesa parts 15, so as to reduce the ON-resistance.

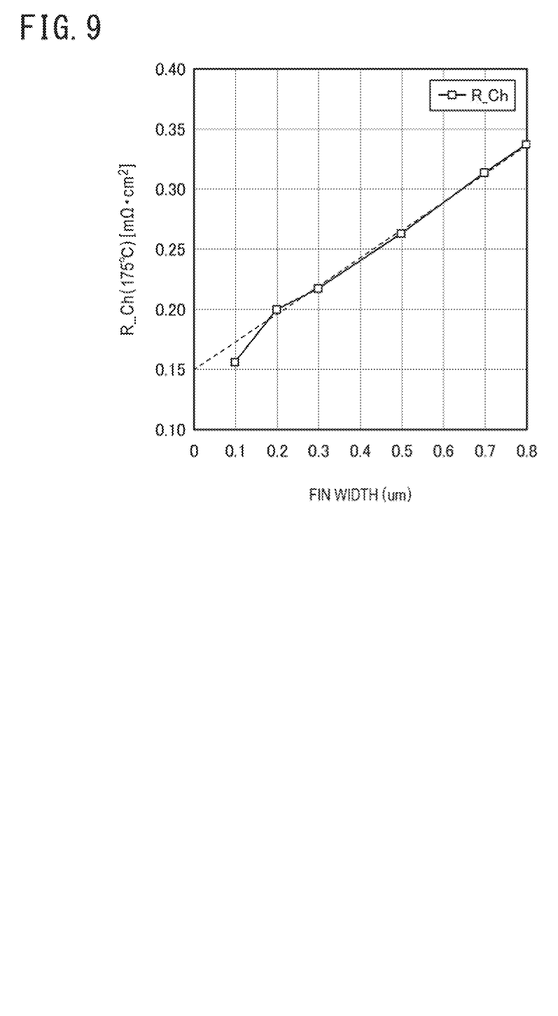

FIG. 9 is a graph of simulation results, showing a relation between a mesa width (FIN width) and a channel resistance (R_Ch) when the trenches have a straight (stripe-shaped) planar pattern, as in the case of the insulated gate semiconductor device of the comparative example. The axis of abscissas in FIG. 9 shows the mesa width (FIN width), and the axis of ordinates in FIG. 9 shows the channel resistance (R_Ch). FIG. 9 indicates a straight line overlapping with plotting points by a broken line. As shown in FIG. 9, the channel resistance is simply decreased with an increase in channel density as the mesa width (FIN width) is decreased to a point immediately before 200 nanometers. The channel resistance is, however, greatly decreased due to the FinFET effect when the mesa width (FIN width) is decreased to 200 nanometers or smaller.

When the mesa parts are arranged in a matrix form, the FinFET effect can be achieved when the mesa width (FIN width) is decreased to 600 nanometers or smaller because the direction capable of ensuring the FinFET effect on the side surfaces of the mesa parts is expanded. When the mesa width (FIN width) is decreased to 400 nanometers or smaller, the arrangement of the mesa parts in a matrix form when each having a rectangular planar pattern facilitates the achievement of the FinFET effect. Further, when the mesa width (FIN width) is decreased to 600 nanometers or smaller, the arrangement of the mesa parts in a matrix form when each having a hexagonal, circular, or elliptic planar pattern facilitates the achievement of the FinFET effect.

### SECOND EMBODIMENT

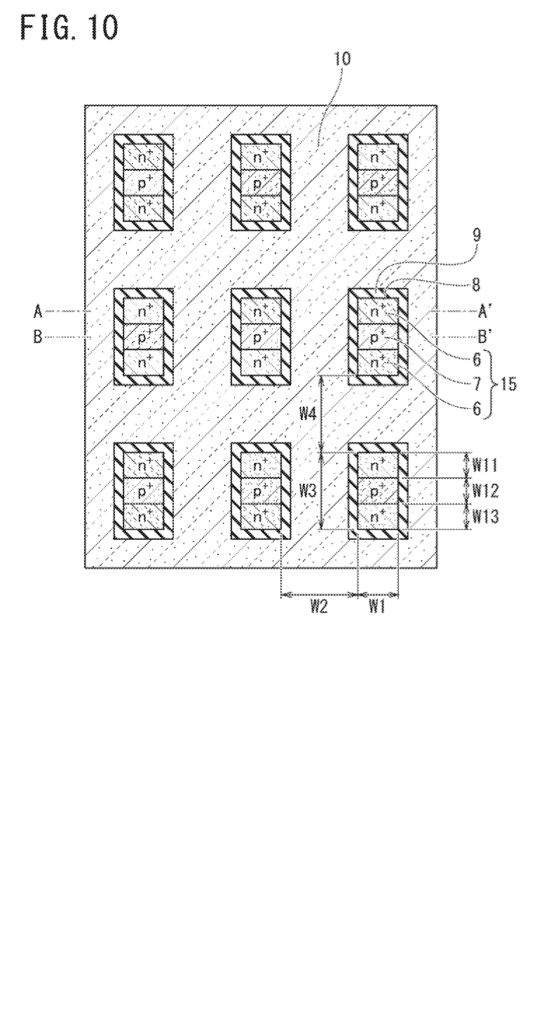

FIG. 10 illustrates a horizontal cross section of an insulated gate semiconductor device according to a second embodiment, corresponding to the horizontal cross section of the insulated gate semiconductor device according to the first embodiment illustrated in FIG. 2. As illustrated in FIG. 10, the insulated gate semiconductor device according to the second embodiment differs from the insulated gate semiconductor device according to the first embodiment illustrated in FIG. 2 in a structure of the respective mesa parts 15 arranged in a matrix form.

The insulated gate semiconductor device according to the second embodiment has a configuration in which the respective mesa parts 15 has a rectangular, particularly oblong, planar pattern with a quadrangular prism. The mesa parts 15 are each defined such that the first direction (the right-left direction in FIG. 10) is a short-side direction, and the second direction (the upper-lower direction in FIG. 10) perpendicular to the first direction is a longitudinal direction. The width W1 of the respective mesa parts 15 in the short-side direction is narrower than the width W3 in the longitudinal direction.

The width W1 of the respective mesa parts 15 in the short-side direction is set to about 600 nanometers or smaller, and may be set to about 400 nanometers or smaller, may be set to about 200 nanometers or smaller, or may be set to about 100 nanometers or smaller, for example. The width W1 of the respective mesa parts 15 in the short-side direction may also be set in a range of about 50 nanometers or greater and 600 nanometers or smaller, may be set in a range of about 50 nanometers or greater and 400 nanometers or smaller, may be set in a range of about 50 nanometers or greater and 200 nanometers or smaller, or may be set in a range of about 50 nanometers or greater and 100 nanometers or smaller, for example.

The width W3 of the respective mesa parts 15 in the longitudinal direction is set to about one micrometer or smaller, and may be set to about 600 nanometers or smaller, may be set to about 400 nanometers or smaller, may be set to about 200 nanometers or smaller, or may be set to about 100 nanometers or smaller, for example. The width W3 of the respective mesa parts 15 in the longitudinal direction may also be set in a range of about 50 nanometers or greater and 1 micrometer or smaller, may be set in a range of about 50 nanometers or greater and 600 nanometers or smaller, may be set in a range of about 50 nanometers or greater and 400 nanometers or smaller, may be set in a range of about 50 nanometers or greater and 200 nanometers or smaller, or may be set in a range of about 50 nanometers or greater and 100 nanometers or smaller, for example.

The mesa parts 15 each include, in the planar pattern, the two n⁺-type source regions 6 located at both ends in the longitudinal direction, and the p⁺-type base contact region 7 interposed between the two source regions 6 so as to be in contact with each other. The widths W11 and W13 of the source regions 6 and the width W12 of the base contact region 7 may be either common to or different from each other in the longitudinal direction of the respective mesa parts 15.

Any of the four side surfaces orthogonal to the four sides of the oblong of the respective mesa parts 15 in the planar pattern may be either an m-plane or an a-plane. For example, the side surfaces in contact with the two sides (long sides) parallel to the longitudinal direction of the respective mesa parts 15 are each defined as an m-plane, and the side surfaces in contact with the two sides (short sides) parallel to the short-side direction of the respective mesa parts 15 are each defined as an a-plane.

The other configurations of the insulated gate semiconductor device according to the second embodiment are substantially the same as those of the insulated gate semiconductor device according to the first embodiment, and overlapping explanations are not repeated below.

The insulated gate semiconductor device according to the second embodiment has the configuration as described above in which the mesa parts 15 are arranged in a matrix form, and the width W1 of the oblong in the short-side direction of the respective mesa parts 15 in the planar pattern is decreased to 600 nanometers or smaller. This configuration can ensure the FinFET effect on the side surfaces of the respective mesa parts 15, so as to reduce ON-resistance. Further, decreasing the width W3 of the oblong in the longitudinal direction of the respective mesa parts 15 in the planar pattern to 600 nanometers or smaller, can further enhance the FinFET effect, so as to reduce the ON-resistance more effectively.

### THIRD EMBODIMENT

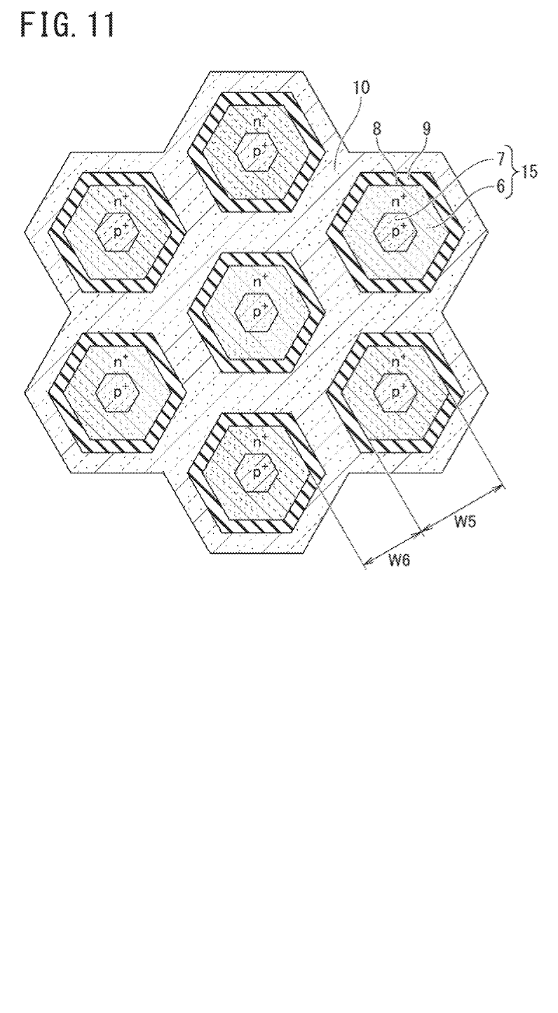

FIG. 11 illustrates a horizontal cross section of an insulated gate semiconductor device according to a third embodiment, corresponding to the horizontal cross section of the insulated gate semiconductor device according to the first embodiment illustrated in FIG. 2. As illustrated in FIG. 11, the insulated gate semiconductor device according to the third embodiment differs from the insulated gate semiconductor device according to the first embodiment illustrated in FIG. 2 in a structure of the respective mesa parts 15 arranged in a matrix (honeycomb) form.

The insulated gate semiconductor device according to the third embodiment has a configuration in which the respective mesa parts 15 has a polygonal, particularly hexagonal, planar pattern with a hexagonal prism. While FIG. 11 illustrates the case in which the six-sided polygonal shape of the respective mesa parts 15 in the planar pattern is a regular hexagon, the respective mesa parts 15 may have a flat six-sided hexagonal shape, instead of the regular hexagon. A width W5 between two sides opposed to each other in the respective mesa parts 15 may be greater than, may be common to, or may be narrower than a width W6 of the respective trenches 8. The respective side surfaces of the hexagonal prism may be a curved surface convex outward. The corners between the respective side surfaces adjacent to each other in the hexagonal prism may each have a curvature.

The width W5 of the respective mesa parts 15 is set to about 600 nanometers or smaller, and may be set to about 400 nanometers or smaller, may be set to about 200 nanometers or smaller, or may be set to about 100 nanometers or smaller, for example. The width W5 of the respective mesa parts 15 may also be set in a range of about 50 nanometers or greater and 600 nanometers or smaller, may be set in a range of about 50 nanometers or greater and 400 nanometers or smaller, may be set in a range of about 50 nanometers or greater and 200 nanometers or smaller, or may be set in a range of about 50 nanometers or greater and 100 nanometers or smaller, for example.

Any of the six side surfaces orthogonal to the respective sides of the hexagon of the respective mesa parts 15 in the planar pattern may be either an m-plane or an a-plane. For example, all of the six side surfaces orthogonal to the respective sides of the hexagon of the respective mesa parts 15 in the planar pattern may be an m-plane.

The mesa parts 15 each include, in the planar pattern, the p⁺-type base contact region 7 and the n⁺-type source region 6 arranged to surround the circumference of the base contact region 7. The base contact region 7 has a hexagonal planar pattern. The source region 6 has a ring-shaped (frame-shaped) planar pattern with the inner circumference and the outer circumference each having a hexagonal shape.

The other configurations of the insulated gate semiconductor device according to the third embodiment are substantially the same as those of the insulated gate semiconductor device according to the first embodiment, and overlapping explanations are not repeated below.

The insulated gate semiconductor device according to the third embodiment has the configuration as described above in which the mesa parts 15 are arranged in a matrix form, and the width W5 between the two sides opposed to each other in the hexagon of the respective mesa parts 15 in the planar pattern is decreased to 600 nanometers or smaller. This configuration can ensure the FinFET effect on the side surfaces of the respective mesa parts 15, so as to reduce ON-resistance.

### FOURTH EMBODIMENT

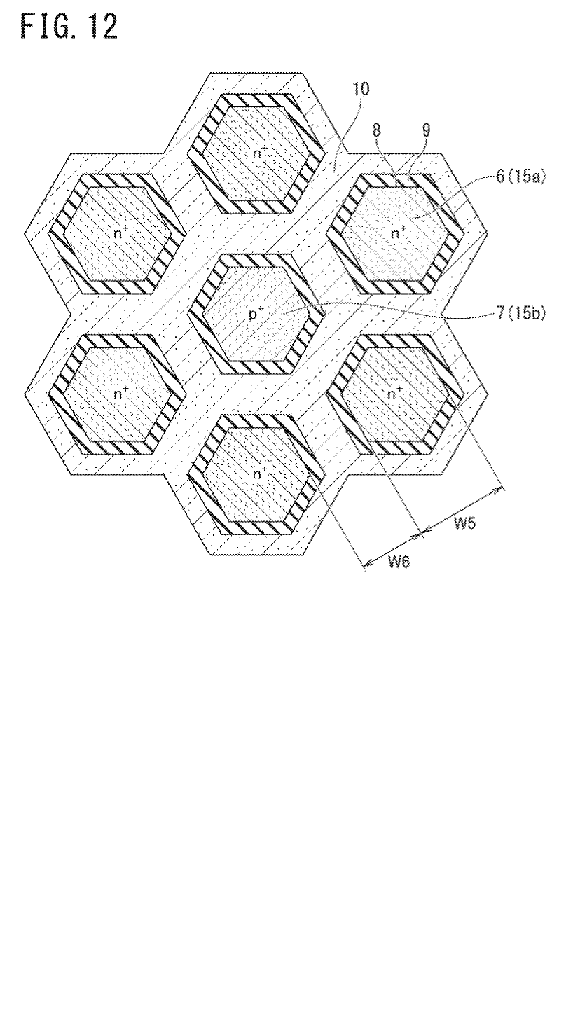

FIG. 12 illustrates a horizontal cross section of an insulated gate semiconductor device according to a fourth embodiment, corresponding to the horizontal cross section of the insulated gate semiconductor device according to the first embodiment illustrated in FIG. 2. As illustrated in FIG. 12, the insulated gate semiconductor device according to the fourth embodiment differs from the insulated gate semiconductor device according to the first embodiment illustrated in FIG. 2 in a structure of the respective mesa parts 15a and 15b arranged in a matrix (honeycomb) form.

The insulated gate semiconductor device according to the fourth embodiment includes two types of the mesa parts 15a and 15b. The mesa part 15a includes the n⁺-type source region 6 in the planar pattern. The mesa part 15b includes the p⁺-type base contact region 7 in the planar pattern. The mesa part 15a and the mesa part 15b are arranged adjacent to each other. The present embodiment illustrates the case in which the six mesa parts 15a are arranged to surround the circumference of the single mesa part 15b.

The respective mesa parts 15a and the mesa part 15b have a common outline. The respective mesa parts 15a and 15b have a polygonal, particularly hexagonal, planar pattern. The width W5 between the two sides opposed to each other in the respective mesa parts 15a and 15b may be greater than, may be common to, or may be narrower than the width W6 of the respective trenches 8.

The width W5 of the respective mesa parts 15a and 15b is set to about 600 nanometers or smaller, and may be set to about 400 nanometers or smaller, may be set to about 200 nanometers or smaller, or may be set to about 100 nanometers or smaller, for example. The width W5 of the respective mesa parts 15a and 15b may also be set in a range of about 50 nanometers or greater and 600 nanometers or smaller, may be set in a range of about 50 nanometers or greater and 400 nanometers or smaller, may be set in a range of about 50 nanometers or greater and 200 nanometers or smaller, or may be set in a range of about 50 nanometers or greater and 100 nanometers or smaller, for example.

Any of the six side surfaces orthogonal to the respective sides of the hexagon of the respective mesa parts 15a and 15b in the planar pattern may be either an m-plane or an a-plane. For example, all of the six side surfaces orthogonal to the respective sides of the hexagon of the respective mesa parts 15a and 15b in the planar pattern may be an m-plane.

The other configurations of the insulated gate semiconductor device according to the fourth embodiment are substantially the same as those of the insulated gate semiconductor device according to the first embodiment, and overlapping explanations are not repeated below.

The insulated gate semiconductor device according to the fourth embodiment has the configuration as described above in which the mesa parts 15a and 15b are arranged in a matrix form, and the width W5 between the two sides opposed to each other in the hexagon of the respective mesa parts 15a and 15b in the planar pattern is decreased to 600 nanometers or smaller. This configuration can ensure the FinFET effect on the side surfaces of the respective mesa parts 15a and 15b, so as to reduce ON-resistance.

### FIFTH EMBODIMENT

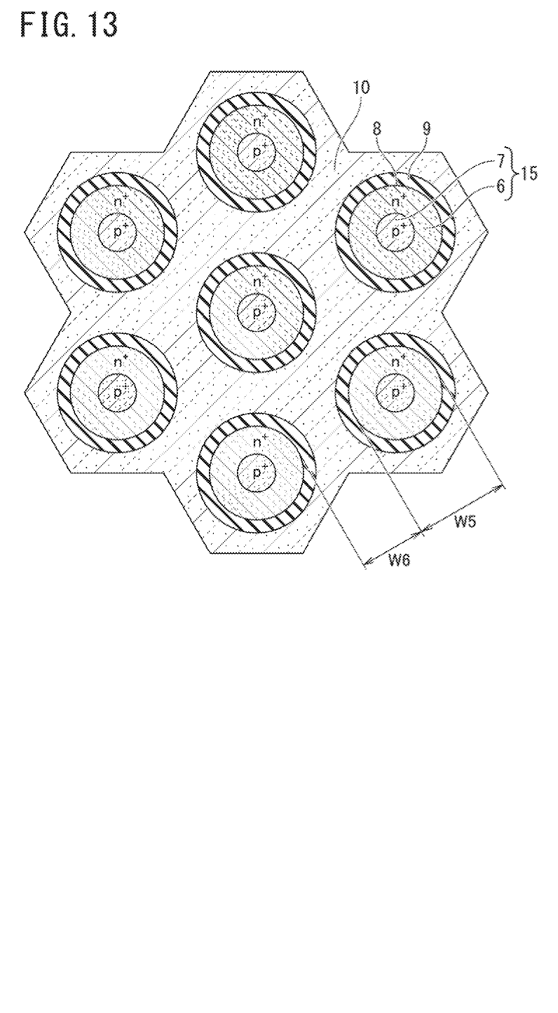

FIG. 13 illustrates a horizontal cross section of an insulated gate semiconductor device according to a fifth embodiment, corresponding to the horizontal cross section of the insulated gate semiconductor device according to the first embodiment illustrated in FIG. 2. As illustrated in FIG. 13, the insulated gate semiconductor device according to the fifth embodiment differs from the insulated gate semiconductor device according to the first embodiment illustrated in FIG. 2 in a structure of the respective mesa parts 15 arranged in a matrix (honeycomb) form.

The insulated gate semiconductor device according to the fifth embodiment has a configuration in which the respective mesa parts 15 have a circular planar pattern with a circular cylinder. The width W5, which is a diameter of the respective mesa parts 15, may be greater than, may be common to, or may be narrower than the width W6 of the respective trenches 8.

The width W5 of the respective mesa parts 15 is set to about 600 nanometers or smaller, and may be set to about 400 nanometers or smaller, may be set to about 200 nanometers or smaller, or may be set to about 100 nanometers or smaller, for example. The width W5 of the respective mesa parts 15 may also be set in a range of about 50 nanometers or greater and 600 nanometers or smaller, may be set in a range of about 50 nanometers or greater and 400 nanometers or smaller, may be set in a range of about 50 nanometers or greater and 200 nanometers or smaller, or may be set in a range of about 50 nanometers or greater and 100 nanometers or smaller, for example.

The mesa parts 15 each include, in the planar pattern, the p⁺-type base contact region 7 and the n⁺-type source region 6 arranged to surround the circumference of the base contact region 7. The base contact region 7 has a circular planar pattern. The source region 6 has a ring-shaped (frame-shaped) planar pattern with the inner circumference and the outer circumference each having a circular shape.

While FIG. 13 illustrates the case in which the mesa parts 15 each have a circular planar pattern, the respective mesa parts 15 may have an elliptic planar pattern. The other configurations of the insulated gate semiconductor device according to the fifth embodiment are substantially the same as those of the insulated gate semiconductor device according to the first embodiment, and overlapping explanations are not repeated below.

The insulated gate semiconductor device according to the fifth embodiment has the configuration as described above in which the mesa parts 15 are arranged in a matrix form, and the width W5 that is the diameter of the circle of the respective mesa parts 15 in the planar pattern is decreased to 600 nanometers or smaller. This configuration can ensure the FinFET effect on the side surfaces of the respective mesa parts 15, so as to reduce ON-resistance.

### SIXTH EMBODIMENT

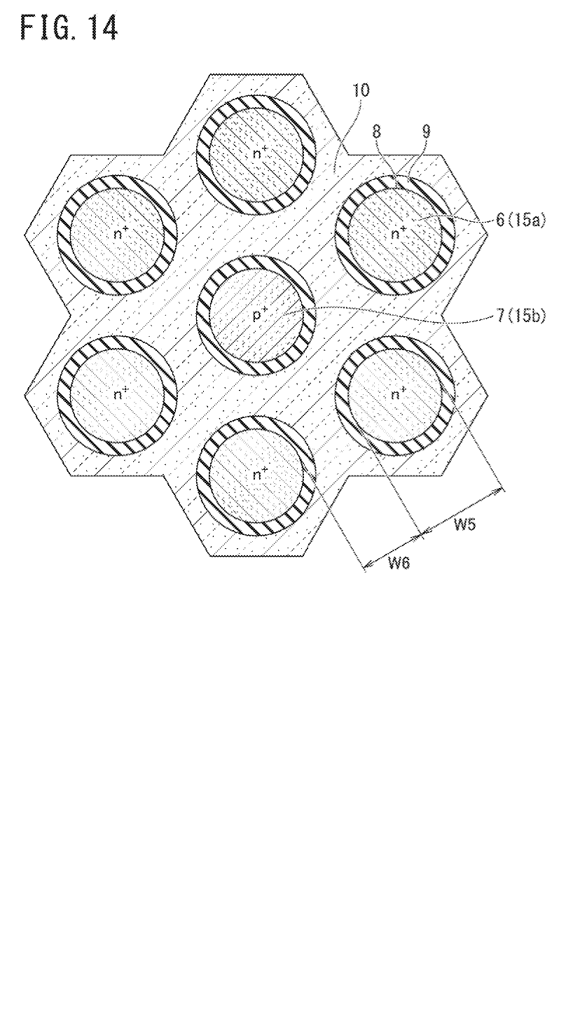

FIG. 14 illustrates a horizontal cross section of an insulated gate semiconductor device according to a sixth embodiment, corresponding to the horizontal cross section of the insulated gate semiconductor device according to the first embodiment illustrated in FIG. 2. As illustrated in FIG. 14, the insulated gate semiconductor device according to the sixth embodiment differs from the insulated gate semiconductor device according to the first embodiment illustrated in FIG. 2 in a structure of the respective mesa parts 15a and 15b arranged in a matrix form.

The insulated gate semiconductor device according to the sixth embodiment includes two types of the mesa parts 15a and 15b. The mesa part 15a includes the n⁺-type source region 6 in the planar pattern. The mesa part 15b includes the p⁺-type base contact region 7 in the planar pattern. The mesa part 15a and the mesa part 15b are arranged adjacent to each other. The present embodiment illustrates the case in which the six mesa parts 15a are arranged to surround the circumference of the single mesa part 15b.

The respective mesa parts 15a and 15b have a circular planar pattern. The respective mesa parts 15a and the mesa part 15b have a common outline. The width W5, which is a diameter of the respective mesa parts 15a and 15b, may be greater than, may be common to, or may be narrower than the width W6 of the respective trenches 8.

The width W5 of the respective mesa parts 15a and 15b is set to about 600 nanometers or smaller, and may be set to about 400 nanometers or smaller, may be set to about 200 nanometers or smaller, or may be set to about 100 nanometers or smaller, for example. The width W5 of the respective mesa parts 15a and 15b may also be set in a range of about 50 nanometers or greater and 600 nanometers or smaller, may be set in a range of about 50 nanometers or greater and 400 nanometers or smaller, may be set in a range of about 50 nanometers or greater and 200 nanometers or smaller, or may be set in a range of about 50 nanometers or greater and 100 nanometers or smaller, for example.

While FIG. 14 illustrates the case in which the mesa parts 15a and 15b each have a circular planar pattern, the respective mesa parts 15a and 15b may have an elliptic planar pattern. The other configurations of the insulated gate semiconductor device according to the sixth embodiment are substantially the same as those of the insulated gate semiconductor device according to the first embodiment, and overlapping explanations are not repeated below.

The insulated gate semiconductor device according to the sixth embodiment has the configuration as described above in which the mesa parts 15a and 15b are arranged in a matrix form, and the width W5 that is the diameter of the circle of the respective mesa parts 15a and 15b in the planar pattern is decreased to 600 nanometers or smaller. This configuration can ensure the FinFET effect on the side surfaces of the respective mesa parts 15a and 15b, so as to reduce ON-resistance.

### SEVENTH EMBODIMENT

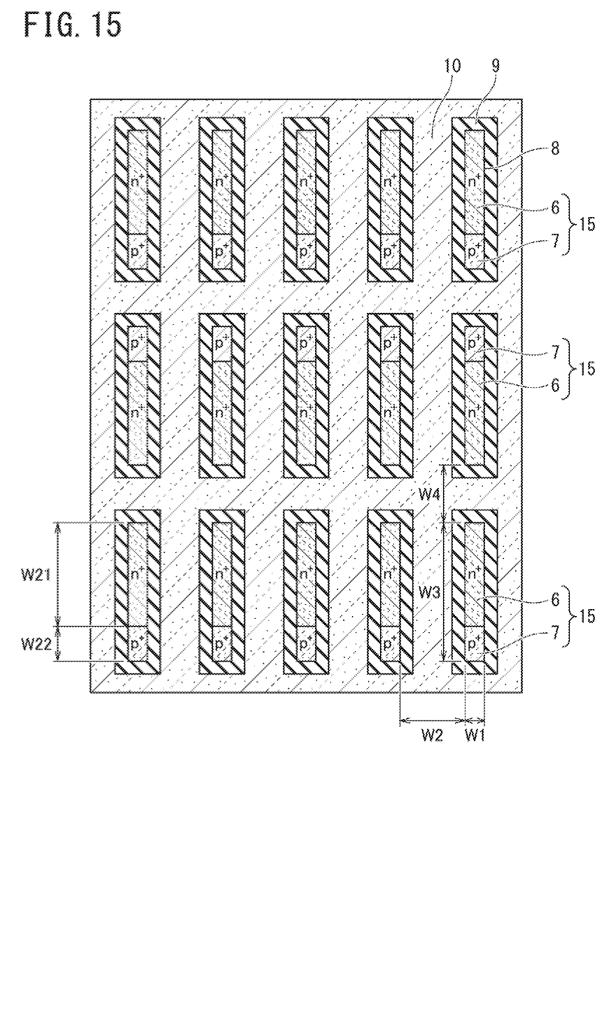

FIG. 15 illustrates a horizontal cross section of an insulated gate semiconductor device according to a seventh embodiment, corresponding to the horizontal cross section of the insulated gate semiconductor device according to the first embodiment illustrated in FIG. 2. As illustrated in FIG. 15, the insulated gate semiconductor device according to the seventh embodiment differs from the insulated gate semiconductor device according to the first embodiment illustrated in FIG. 2 in a structure of the respective mesa parts 15 arranged in a matrix form (a rectangular array).

The insulated gate semiconductor device according to the seventh embodiment has a configuration in which the mesa parts 15 each include, in the planar pattern, the n⁺-type source region 6 and the p⁺-type base contact region 7 in contact with the source region 6 in the longitudinal direction of the respective mesa parts 15. A width W21 of the source region 6 is greater than a width W22 of the base contact region 7 in the longitudinal direction of the respective mesa parts 15.

The respective source regions 6 in the mesa parts 15 adjacent to each other are opposed to each other, and the respective base contact regions 7 in the mesa parts 15 adjacent to each other are opposed to each other in the first direction (the right-left direction in FIG. 15). The respective source regions 6 in the mesa parts 15 adjacent to each other are opposed to each other, and the respective base contact regions 7 in the mesa parts 15 adjacent to each other are opposed to each other in the second direction (the upper-lower direction in FIG. 15). Namely, the respective mesa parts 15 located adjacent to each other in the second direction (the upper-lower direction in FIG. 15) are arranged in the directions opposite to each other.

The respective mesa parts 15 have a rectangular, particularly oblong, planar pattern. The mesa parts 15 are each defined such that the first direction (the right-left direction in FIG. 15) is a short-side direction, and the second direction (the upper-lower direction in FIG. 15) is a longitudinal direction. The width W1 of the respective mesa parts 15 in the short-side direction is narrower than the width W3 of the respective mesa parts 15 in the longitudinal direction.

The width W1 of the respective mesa parts 15 in the short-side direction is set to about 600 nanometers or smaller, and may be set to about 400 nanometers or smaller, may be set to about 200 nanometers or smaller, or may be set to about 100 nanometers or smaller, for example. The width W1 of the respective mesa parts 15 in the short-side direction may also be set in a range of about 50 nanometers or greater and 600 nanometers or smaller, may be set in a range of about 50 nanometers or greater and 400 nanometers or smaller, may be set in a range of about 50 nanometers or greater and 200 nanometers or smaller, or may be set in a range of about 50 nanometers or greater and 100 nanometers or smaller, for example.

The width W3 of the respective mesa parts 15 in the longitudinal direction is set to about 2 micrometers or smaller, and may be set to about 1 micrometer or smaller, may be set to about 600 nanometers or smaller, may be set to about 400 nanometers or smaller, may be set to about 200 nanometers or smaller, or may be set to about 100 nanometers or smaller, for example. The width W3 of the respective mesa parts 15 in the longitudinal direction may also be set in a range of about 50 nanometers or greater and 2 micrometers or smaller, may be set in a range of about 50 nanometers or greater and 1 micrometer or smaller, may be set in a range of about 50 nanometers or greater and 600 nanometers or smaller, may be set in a range of about 50 nanometers or greater and 400 nanometers or smaller, may be set in a range of about 50 nanometers or greater and 200 nanometers or smaller, or may be set in a range of about 50 nanometers or greater and 100 nanometers or smaller, for example.

Any of the four side surfaces orthogonal to the four sides of the oblong of the respective mesa parts 15 in the planar pattern may be either an m-plane or an a-plane. For example, the side surfaces in contact with the two sides in the longitudinal direction of the respective mesa parts 15 are each defined as an m-plane, and the side surfaces in contact with the two sides in the short-side direction of the respective mesa parts 15 are each defined as an a-plane.

While FIG. 15 illustrates the case in which the outline of the respective mesa parts 15 has an oblong shape, the outline may be any other polygonal shapes such as a square and a hexagon, or may be a circular or elliptic shape instead. In addition, the mesa part 15 only including the source region 6 may be additionally arranged between the two mesa parts 15 in which the source regions 6 are adjacent to each other along the short sides. Similarly, the mesa part 15 only including the base contact region 7 may be additionally arranged between the two mesa parts 15 in which the base contact regions 7 are adjacent to each other along the short sides. The other configurations of the insulated gate semiconductor device according to the seventh embodiment are substantially the same as those of the insulated gate semiconductor device according to the first embodiment, and overlapping explanations are not repeated below.

The insulated gate semiconductor device according to the seventh embodiment has the configuration as described above in which the mesa parts 15 are arranged in a matrix form, and the width W1 of the oblong in the short-side direction of the respective mesa parts 15 in the planar pattern is decreased to 600 nanometers or smaller. This configuration can ensure the FinFET effect on the side surfaces of the respective mesa parts 15, so as to reduce ON-resistance. Further, decreasing the width W3 of the oblong in the longitudinal direction of the respective mesa parts 15 in the planar pattern to 600 nanometers or smaller, can further enhance the FinFET effect, so as to reduce the ON-resistance more effectively.

The present embodiment also has the configuration in which the source regions 6 in the mesa parts 15 adjacent to each other are opposed to each other, and the base contact regions 7 in the mesa parts 15 adjacent to each other are opposed to each other in the second direction (the upper-lower direction in FIG. 15). This configuration enables an ion implantation step for forming each of the source regions 6 and the base contact regions 7 to provide openings in an ion implantation mask concurrently in plural regions during the manufacture of the insulated gate semiconductor device according to the seventh embodiment. Namely, the opening width of the openings in the mask can be widely ensured.

### EIGHTH EMBODIMENT

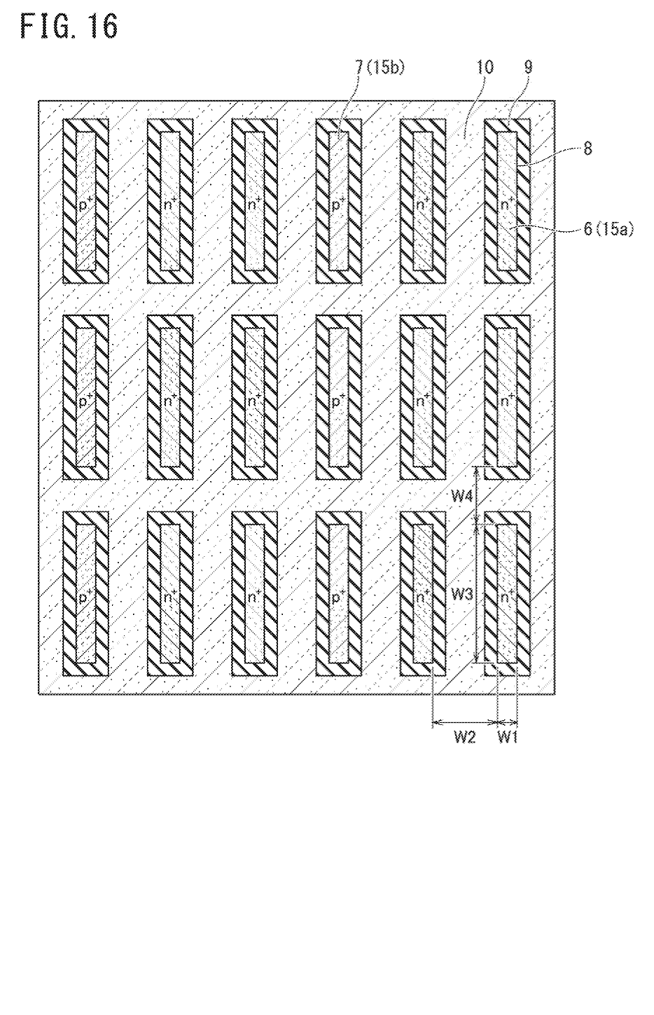

FIG. 16 illustrates a horizontal cross section of an insulated gate semiconductor device according to an eighth embodiment, corresponding to the horizontal cross section of the insulated gate semiconductor device according to the first embodiment illustrated in FIG. 2. As illustrated in FIG. 16, the insulated gate semiconductor device according to the eighth embodiment differs from the insulated gate semiconductor device according to the first embodiment illustrated in FIG. 2 in a structure of the respective mesa parts 15a and 15b arranged in a matrix form (a rectangular array).

The insulated gate semiconductor device according to the eighth embodiment includes two types of the mesa parts 15a and 15b. The mesa part 15a includes the n⁺-type source region 6 in the planar pattern. The mesa part 15b includes the p⁺-type base contact region 7 in the planar pattern. The two types of the mesa parts 15a and 15b are arranged adjacent to each other.

At least one mesa part 15a and at least one mesa part 15b are alternately and repeatedly arranged in the first direction (the right-left direction in FIG. 16). The present embodiment illustrates the case of including a set of a plurality of (two) mesa parts 15a and one mesa part 15b alternately and repeatedly arranged. The mesa parts 15a and the mesa parts 15b are each arranged in series in the second direction (the upper-lower direction in FIG. 16) perpendicular to the first direction. Alternatively, the mesa parts 15a and the mesa parts 15b may be arranged repeatedly in the second direction and each arranged in series in the first direction.

The mesa parts 15a and the mesa parts 15b have a common outline. The respective mesa parts 15a and 15b have a rectangular, particularly oblong, planar pattern. The mesa parts 15a and 15b are each defined such that the first direction (the right-left direction in FIG. 16) is a short-side direction, and the second direction (the upper-lower direction in FIG. 16) is a longitudinal direction. The width W1 of the respective mesa parts 15a and 15b in the short-side direction is narrower than the width W3 of the respective mesa parts 15a and 15b in the longitudinal direction.

The width W1 of the respective mesa parts 15a and 15b in the short-side direction is set to about 600 nanometers or smaller, and may be set to about 400 nanometers or smaller, may be set to about 200 nanometers or smaller, or may be set to about 100 nanometers or smaller, for example. The width W1 of the respective mesa parts 15a and 15b in the short-side direction may also be set in a range of about 50 nanometers or greater and 600 nanometers or smaller, may be set in a range of about 50 nanometers or greater and 400 nanometers or smaller, may be set in a range of about 50 nanometers or greater and 200 nanometers or smaller, or may be set in a range of about 50 nanometers or greater and 100 nanometers or smaller, for example.

The width W3 of the respective mesa parts 15a and 15b in the longitudinal direction is set to about 2 micrometers or smaller, and may be set to about 1 micrometer or smaller, may be set to about 600 nanometers or smaller, may be set to about 400 nanometers or smaller, may be set to about 200 nanometers or smaller, or may be set to about 100 nanometers or smaller, for example. The width W3 of the respective mesa parts 15a and 15b in the longitudinal direction may also be set in a range of about 50 nanometers or greater and 2 micrometers or smaller, may be set in a range of about 50 nanometers or greater and 1 micrometer or smaller, may be set in a range of about 50 nanometers or greater and 600 nanometers or smaller, may be set in a range of about 50 nanometers or greater and 400 nanometers or smaller, may be set in a range of about 50 nanometers or greater and 200 nanometers or smaller, or may be set in a range of about 50 nanometers or greater and 100 nanometers or smaller, for example.

Any of the four side surfaces orthogonal to the four sides of the oblong of the respective mesa parts 15a and 15b in the planar pattern may be either an m-plane or an a-plane. For example, the side surfaces in contact with the two sides in the longitudinal direction of the respective mesa parts 15a and 15b are each defined as an m-plane, and the side surfaces in contact with the two sides in the short-side direction of the respective mesa parts 15a and 15b are each defined as an a-plane.

While FIG. 16 illustrates the case in which the outline of the respective mesa parts 15a and 15b has an oblong shape, the outline may be any other polygonal shapes such as a square and a hexagon, or may be a circular or elliptic shape instead. The other configurations of the insulated gate semiconductor device according to the eighth embodiment are substantially the same as those of the insulated gate semiconductor device according to the first embodiment, and overlapping explanations are not repeated below.

The insulated gate semiconductor device according to the eighth embodiment has the configuration as described above in which the mesa parts 15a and 15b are arranged in a matrix form, and the width W1 of the oblong in the short-side direction of the respective mesa parts 15a and 15b in the planar pattern is decreased to 600 nanometers or smaller. This configuration can ensure the FinFET effect on the side surfaces of the respective mesa parts 15a and 15b, so as to reduce ON-resistance. Further, decreasing the width W3 of the oblong in the longitudinal direction of the respective mesa parts 15a and 15b in the planar pattern to 600 nanometers or smaller, can further enhance the FinFET effect, so as to reduce the ON-resistance more effectively.

The present embodiment also has the configuration in which the mesa parts 15a and the mesa parts 15b are each arranged in series in the second direction (the upper-lower direction in FIG. 16) perpendicular to the first direction. This configuration enables the ion implantation step for forming each of the source regions 6 and the base contact regions 7 to provide openings in an ion implantation mask concurrently in plural regions during the manufacture of the insulated gate semiconductor device according to the eighth embodiment.

### NINTH EMBODIMENT

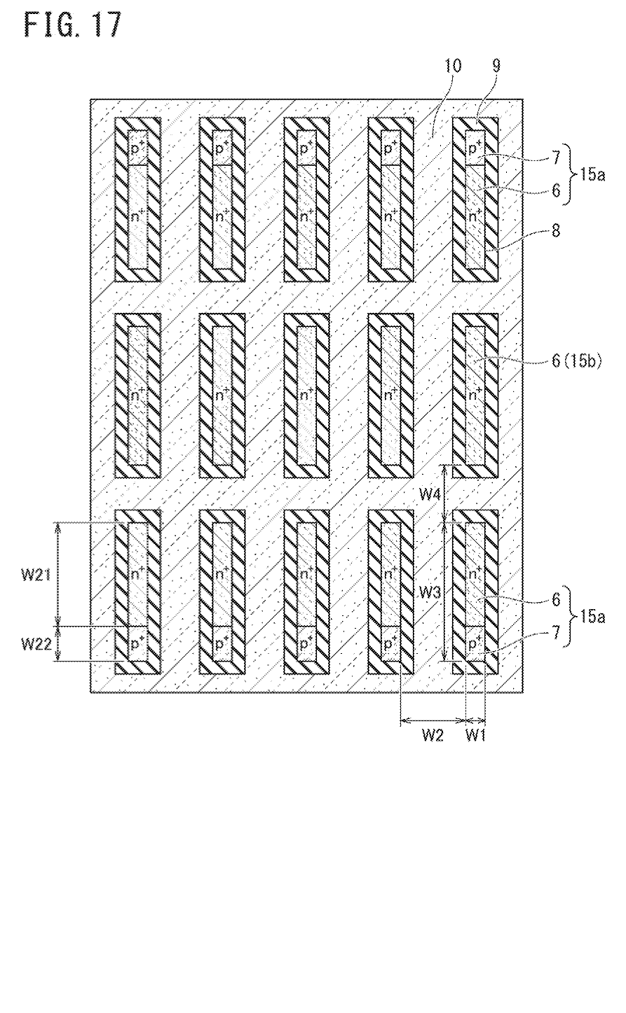

FIG. 17 illustrates a horizontal cross section of an insulated gate semiconductor device according to a ninth embodiment, corresponding to the horizontal cross section of the insulated gate semiconductor device according to the first embodiment illustrated in FIG. 2. As illustrated in FIG. 17, the insulated gate semiconductor device according to the ninth embodiment differs from the insulated gate semiconductor device according to the seventh embodiment illustrated in FIG. 15 in a structure of the respective mesa parts 15a and 15b arranged in a matrix form (a rectangular array). In particular, the present embodiment has a configuration in which the mesa part only including the source regions 6 is additionally arranged between the two mesa parts 15 adjacent to each other in which the source regions 6 are adjacent to each other along the short sides illustrated in FIG. 15.

The insulated gate semiconductor device according to the ninth embodiment includes two types of the mesa parts 15a and 15b. The respective mesa parts 15a include the n⁺-type source region 6, and the p⁺-type base contact region 7 in contact with the source region 6 in the longitudinal direction in the planar pattern. The width W21 of the source region 6 is greater than the width W22 of the base contact region 7 in the longitudinal direction of the respective mesa parts 15a. The respective mesa parts 15b include the n⁺-type source region 6 in the planar pattern.

The mesa parts 15a and 15b are each repeatedly arranged in the first direction (the right-left direction in FIG. 17). A structure in which the two mesa parts 15a interpose the single mesa part 15b is repeatedly arranged in the second direction (the upper-lower direction in FIG. 17) perpendicular to the first direction. The source regions 6 in the respective mesa parts 15a are opposed to the source regions 6 in the respective mesa parts 15b adjacent to the mesa parts 15a in the second direction (the upper-lower direction in FIG. 17). Although not illustrated in FIG. 17, the base contact regions 7 in the mesa parts 15a adjacent to each other are opposed to each other in the second direction (the upper-lower direction in FIG. 17).

The mesa parts 15a and the mesa parts 15b have a common outline. The respective mesa parts 15a and 15b have a rectangular, particularly oblong, planar pattern. The mesa parts 15a and 15b are each defined such that the first direction (the right-left direction in FIG. 17) is a short-side direction, and the second direction (the upper-lower direction in FIG. 17) is a longitudinal direction. The width W1 of the respective mesa parts 15a and 15b in the short-side direction is narrower than the width W3 of the respective mesa parts 15a and 15b in the longitudinal direction.

The width W1 of the respective mesa parts 15a and 15b in the short-side direction is set to about 600 nanometers or smaller, and may be set to about 400 nanometers or smaller, may be set to about 200 nanometers or smaller, or may be set to about 100 nanometers or smaller, for example. The width W1 of the respective mesa parts 15a and 15b in the short-side direction may also be set in a range of about 50 nanometers or greater and 600 nanometers or smaller, may be set in a range of about 50 nanometers or greater and 400 nanometers or smaller, may be set in a range of about 50 nanometers or greater and 200 nanometers or smaller, or may be set in a range of about 50 nanometers or greater and 100 nanometers or smaller, for example.

The width W3 of the respective mesa parts 15a and 15b in the longitudinal direction is set to about 2 micrometers or smaller, and may be set to about 1 micrometer or smaller, may be set to about 600 nanometers or smaller, may be set to about 400 nanometers or smaller, may be set to about 200 nanometers or smaller, or may be set to about 100 nanometers or smaller, for example. The width W3 of the respective mesa parts 15a and 15b in the longitudinal direction may also be set in a range of about 50 nanometers or greater and 2 micrometers or smaller, may be set in a range of about 50 nanometers or greater and 1 micrometer or smaller, may be set in a range of about 50 nanometers or greater and 600 nanometers or smaller, may be set in a range of about 50 nanometers or greater and 400 nanometers or smaller, may be set in a range of about 50 nanometers or greater and 200 nanometers or smaller, or may be set in a range of about 50 nanometers or greater and 100 nanometers or smaller, for example.

Any of the four side surfaces orthogonal to the four sides of the oblong of the respective mesa parts 15a and 15b in the planar pattern may be either an m-plane or an a-plane. For example, the side surfaces in contact with the two sides in the longitudinal direction of the respective mesa parts 15a and 15b are each defined as an m-plane, and the side surfaces in contact with the two sides in the short-side direction of the respective mesa parts 15a and 15b are each defined as an a-plane.

While FIG. 17 illustrates the case in which the outline of the respective mesa parts 15a and 15b has an oblong shape, the outline may be any other polygonal shapes such as a square and a hexagon, or may be a circular or elliptic shape instead. The other configurations of the insulated gate semiconductor device according to the ninth embodiment are substantially the same as those of the insulated gate semiconductor device according to the first embodiment, and overlapping explanations are not repeated below.

The insulated gate semiconductor device according to the ninth embodiment has the configuration as described above in which the mesa parts 15a and 15b are arranged in a matrix form, and the width W1 of the oblong in the short-side direction of the respective mesa parts 15a and 15b in the planar pattern is decreased to 600 nanometers or smaller. This configuration can ensure the FinFET effect on the side surfaces of the respective mesa parts 15a and 15b, so as to reduce ON-resistance. Further, decreasing the width W3 of the oblong in the longitudinal direction of the respective mesa parts 15a and 15b in the planar pattern to 600 nanometers or smaller, can further enhance the FinFET effect, so as to reduce the ON-resistance more effectively.

The present embodiment also has the configuration in which the source regions 6 in the respective mesa parts 15a are opposed to the source regions 6 in the respective mesa parts 15b in the second direction (the upper-lower direction in FIG. 17), and the respective base contact regions 7 in the mesa parts 15a adjacent to each other are opposed to each other in the second direction. This configuration enables the ion implantation step for forming each of the source regions 6 and the base contact regions 7 to provide openings in an ion implantation mask concurrently in plural regions during the manufacture of the insulated gate semiconductor device according to the ninth embodiment.

### TENTH EMBODIMENT

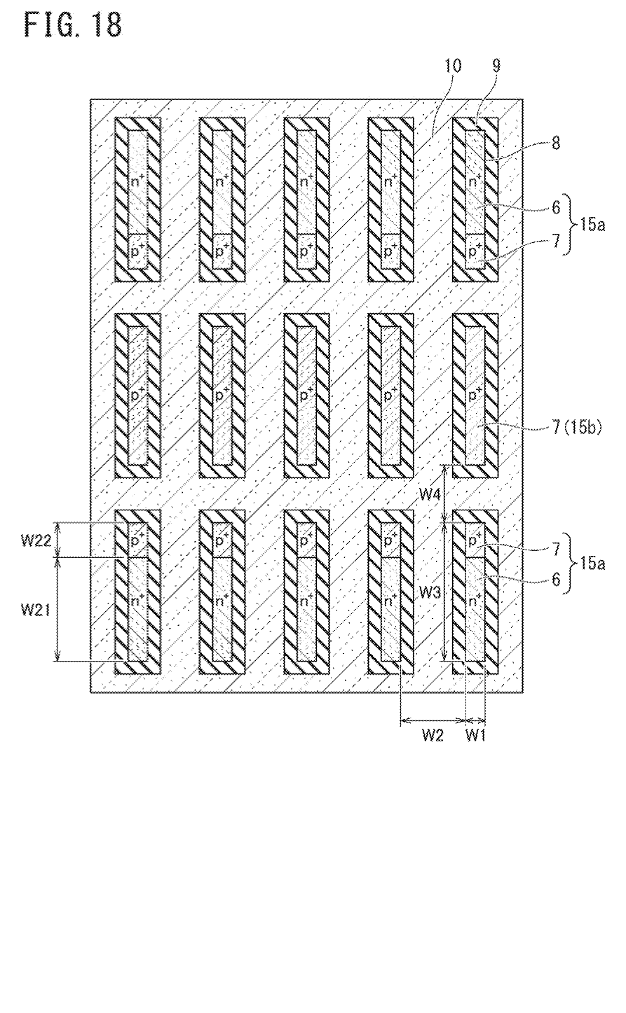

FIG. 18 illustrates a horizontal cross section of an insulated gate semiconductor device according to a tenth embodiment, corresponding to the horizontal cross section of the insulated gate semiconductor device according to the first embodiment illustrated in FIG. 2. As illustrated in FIG. 18, the insulated gate semiconductor device according to the tenth embodiment differs from the insulated gate semiconductor device according to the seventh embodiment illustrated in FIG. 15 in a structure of the respective mesa parts 15a and 15b arranged in a matrix form (a rectangular array). In particular, the present embodiment has a configuration in which the mesa part only including the base contact region 7 is additionally arranged between the two mesa parts 15 adjacent to each other in which the base contact regions 7 are opposed to each other along the short sides illustrated in FIG. 15.

The insulated gate semiconductor device according to the tenth embodiment includes two types of the mesa parts 15a and 15b. The respective mesa parts 15a include the n⁺-type source region 6, and the p⁺-type base contact region 7 in contact with the source region 6 in the longitudinal direction in the planar pattern. The width W21 of the source region 6 is greater than the width W22 of the base contact region 7 in the longitudinal direction of the respective mesa parts 15a. The respective mesa parts 15b include the p⁺-type base contact region 7 in the planar pattern.

The mesa parts 15a and 15b are each repeatedly arranged in the first direction (the right-left direction in FIG. 18). A structure in which the two mesa parts 15a interpose the single mesa part 15b is repeatedly arranged in the second direction (the upper-lower direction in FIG. 18) perpendicular to the first direction. The base contact regions 7 in the respective mesa parts 15a are opposed to the base contact regions 7 in the respective mesa parts 15b adjacent to the mesa parts 15a in the second direction (the upper-lower direction in FIG. 18). Although not illustrated in FIG. 18, the source regions 6 in the mesa parts 15a adjacent to each other are opposed to each other in the second direction (the upper-lower direction in FIG. 18).

The mesa parts 15a and the mesa parts 15b have a common outline. The respective mesa parts 15a and 15b have a rectangular, particularly oblong, planar pattern. The mesa parts 15a and 15b are each defined such that the first direction (the right-left direction in FIG. 18) is a short-side direction, and the second direction (the upper-lower direction in FIG. 18) is a longitudinal direction. The width W1 of the respective mesa parts 15a and 15b in the short-side direction is narrower than the width W3 of the respective mesa parts 15a and 15b in the longitudinal direction.

The width W1 of the respective mesa parts 15a and 15b in the short-side direction is set to about 600 nanometers or smaller, and may be set to about 400 nanometers or smaller, may be set to about 200 nanometers or smaller, or may be set to about 100 nanometers or smaller, for example. The width W1 of the respective mesa parts 15a and 15b in the short-side direction may also be set in a range of about 50 nanometers or greater and 600 nanometers or smaller, may be set in a range of about 50 nanometers or greater and 400 nanometers or smaller, may be set in a range of about 50 nanometers or greater and 200 nanometers or smaller, or may be set in a range of about 50 nanometers or greater and 100 nanometers or smaller, for example.

The width W3 of the respective mesa parts 15a and 15b in the longitudinal direction is set to about 2 micrometers or smaller, and may be set to about 1 micrometer or smaller, may be set to about 600 nanometers or smaller, may be set to about 400 nanometers or smaller, may be set to about 200 nanometers or smaller, or may be set to about 100 nanometers or smaller, for example. The width W3 of the respective mesa parts 15a and 15b in the longitudinal direction may also be set in a range of about 50 nanometers or greater and 2 micrometers or smaller, may be set in a range of about 50 nanometers or greater and 1 micrometer or smaller, may be set in a range of about 50 nanometers or greater and 600 nanometers or smaller, may be set in a range of about 50 nanometers or greater and 400 nanometers or smaller, may be set in a range of about 50 nanometers or greater and 200 nanometers or smaller, or may be set in a range of about 50 nanometers or greater and 100 nanometers or smaller, for example.

Any of the four side surfaces orthogonal to the four sides of the oblong of the respective mesa parts 15a and 15b in the planar pattern may be either an m-plane or an a-plane. For example, the side surfaces in contact with the two sides in the longitudinal direction of the respective mesa parts 15a and 15b are each defined as an m-plane, and the side surfaces in contact with the two sides in the short-side direction of the respective mesa parts 15a and 15b are each defined as an a-plane.

While FIG. 18 illustrates the case in which the outline of the respective mesa parts 15a and 15b has an oblong shape, the outline may be any other polygonal shapes such as a square and a hexagon, or may be a circular or elliptic shape instead. The other configurations of the insulated gate semiconductor device according to the tenth embodiment are substantially the same as those of the insulated gate semiconductor device according to the first embodiment, and overlapping explanations are not repeated below.

The insulated gate semiconductor device according to the tenth embodiment has the configuration as described above in which the mesa parts 15a and 15b are arranged in a matrix form, and the width W1 of the oblong in the short-side direction of the respective mesa parts 15a and 15b in the planar pattern is decreased to 600 nanometers or smaller. This configuration can ensure the FinFET effect on the side surfaces of the respective mesa parts 15a and 15b, so as to reduce ON-resistance. Further, decreasing the width W3 of the oblong in the longitudinal direction of the respective mesa parts 15a and 15b in the planar pattern to 600 nanometers or smaller, can further enhance the FinFET effect, so as to reduce the ON-resistance more effectively.

The present embodiment also has the configuration in which the base contact regions 7 in the respective mesa parts 15a are opposed to the base contact regions 7 in the respective mesa parts 15b in the second direction (the upper-lower direction in FIG. 18), and the respective source regions 6 in the mesa parts 15a adjacent to each other are opposed to each other in the second direction. This configuration enables the ion implantation step for forming each of the source regions 6 and the base contact regions 7 to provide openings in an ion implantation mask concurrently in plural regions during the manufacture of the insulated gate semiconductor device according to the tenth embodiment.

### ELEVENTH EMBODIMENT

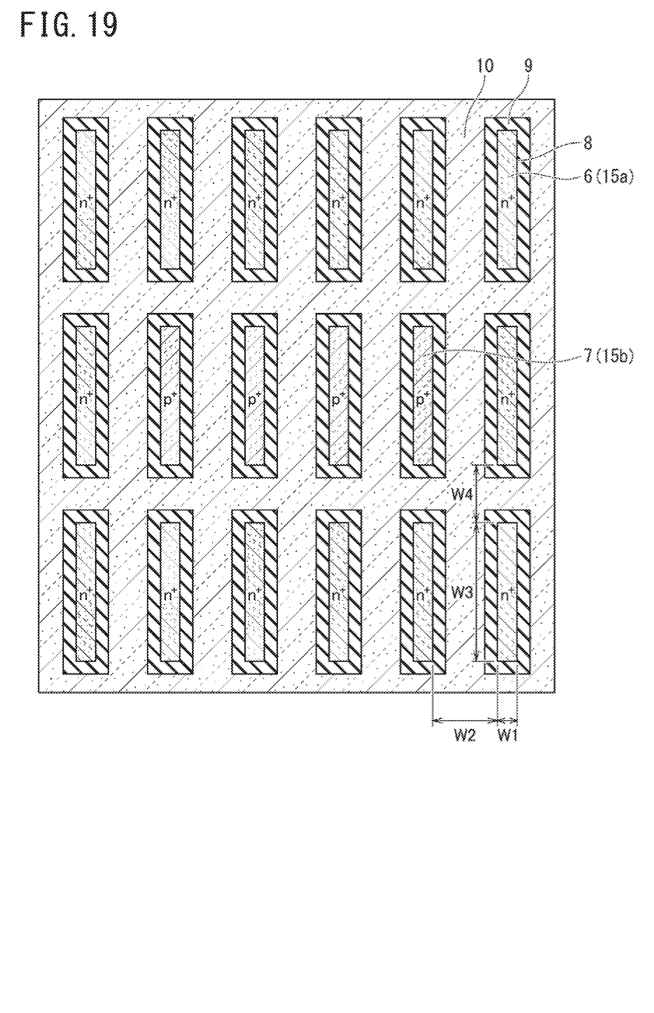

FIG. 19 illustrates a horizontal cross section of an insulated gate semiconductor device according to an eleventh embodiment, corresponding to the horizontal cross section of the insulated gate semiconductor device according to the first embodiment illustrated in FIG. 2. As illustrated in FIG. 19, the insulated gate semiconductor device according to the eleventh embodiment differs from the insulated gate semiconductor device according to the first embodiment illustrated in FIG. 2 in a structure of the respective mesa parts 15a and 15b arranged in a matrix form (a rectangular array).

The insulated gate semiconductor device according to the eleventh embodiment includes two types of the mesa parts 15a and 15b. The respective mesa parts 15a include the n⁺-type source region 6 in the planar pattern. The respective mesa parts 15b include the p⁺-type base contact region 7 in the planar pattern.

The plural (four) mesa parts 15b are arranged in the first direction (right-left direction in FIG. 19). While FIG. 19 illustrates the case in which the four mesa parts 15b are arranged, the number of the mesa parts 15b to be arranged may be changed as appropriate, and may be three or smaller or five or more instead. The plural mesa parts 15a are arranged to surround the circumference of the plural mesa parts 15b. Although not illustrated in FIG. 19, the structure in which the plural mesa parts 15a surrounding the circumference of the plural mesa parts 15b may be repeatedly provided in the first direction (the right-left direction in FIG. 19) and the direction perpendicular to the first direction (the upper-lower direction in FIG. 19).

The mesa parts 15a and the mesa parts 15b have a common outline. The respective mesa parts 15a and 15b have a rectangular, particularly oblong, planar pattern. The mesa parts 15a and 15b are each defined such that the first direction (the right-left direction in FIG. 19) is a short-side direction, and the second direction (the upper-lower direction in FIG. 19) is a longitudinal direction. The width W1 of the respective mesa parts 15a and 15b in the short-side direction is narrower than the width W3 of the respective mesa parts 15a and 15b in the longitudinal direction.

The width W1 of the respective mesa parts 15a and 15b in the short-side direction is set to about 600 nanometers or smaller, and may be set to about 400 nanometers or smaller, may be set to about 200 nanometers or smaller, or may be set to about 100 nanometers or smaller, for example. The width W1 of the respective mesa parts 15a and 15b in the short-side direction may also be set in a range of about 50 nanometers or greater and 600 nanometers or smaller, may be set in a range of about 50 nanometers or greater and 400 nanometers or smaller, may be set in a range of about 50 nanometers or greater and 200 nanometers or smaller, or may be set in a range of about 50 nanometers or greater and 100 nanometers or smaller, for example.

The width W3 of the respective mesa parts 15a and 15b in the longitudinal direction is set to about 2 micrometers or smaller, and may be set to about 1 micrometer or smaller, may be set to about 600 nanometers or smaller, may be set to about 400 nanometers or smaller, may be set to about 200 nanometers or smaller, or may be set to about 100 nanometers or smaller, for example. The width W3 of the respective mesa parts 15a and 15b in the longitudinal direction may also be set in a range of about 50 nanometers or greater and 2 micrometers or smaller, may be set in a range of about 50 nanometers or greater and 1 micrometer or smaller, may be set in a range of about 50 nanometers or greater and 600 nanometers or smaller, may be set in a range of about 50 nanometers or greater and 400 nanometers or smaller, may be set in a range of about 50 nanometers or greater and 200 nanometers or smaller, or may be set in a range of about 50 nanometers or greater and 100 nanometers or smaller, for example.

Any of the four side surfaces orthogonal to the four sides of the oblong of the respective mesa parts 15a and 15b in the planar pattern may be either an m-plane or an a-plane. For example, the side surfaces in contact with the two sides in the longitudinal direction of the respective mesa parts 15a and 15b are each defined as an m-plane, and the side surfaces in contact with the two sides in the short-side direction of the respective mesa parts 15a and 15b are each defined as an a-plane.

While FIG. 19 illustrates the case in which the outline of the respective mesa parts 15a and 15b has an oblong shape, the outline may be any other polygonal shapes such as a square and a hexagon, or may be a circular or elliptic shape instead. The other configurations of the insulated gate semiconductor device according to the eleventh embodiment are substantially the same as those of the insulated gate semiconductor device according to the first embodiment, and overlapping explanations are not repeated below.

The insulated gate semiconductor device according to the eleventh embodiment has the configuration as described above in which the mesa parts 15a and 15b are arranged in a matrix form, and the width W1 of the oblong in the short-side direction of the respective mesa parts 15a and 15b in the planar pattern is decreased to 600 nanometers or smaller. This configuration can ensure the FinFET effect on the side surfaces of the respective mesa parts 15a and 15b, so as to reduce ON-resistance. Further, decreasing the width W3 of the oblong in the longitudinal direction of the respective mesa parts 15a and 15b in the planar pattern to 600 nanometers or smaller, can further enhance the FinFET effect, so as to reduce the ON-resistance more effectively.

The present embodiment also has the configuration in which the plural mesa parts 15a are arranged to surround the circumference of the plural mesa parts 15b, so as to enable the ion implantation step for forming each of the source regions 6 and the base contact regions 7 to provide openings in an ion implantation mask concurrently in plural regions during the manufacture of the insulated gate semiconductor device according to the eleventh embodiment.

### TWELFTH EMBODIMENT

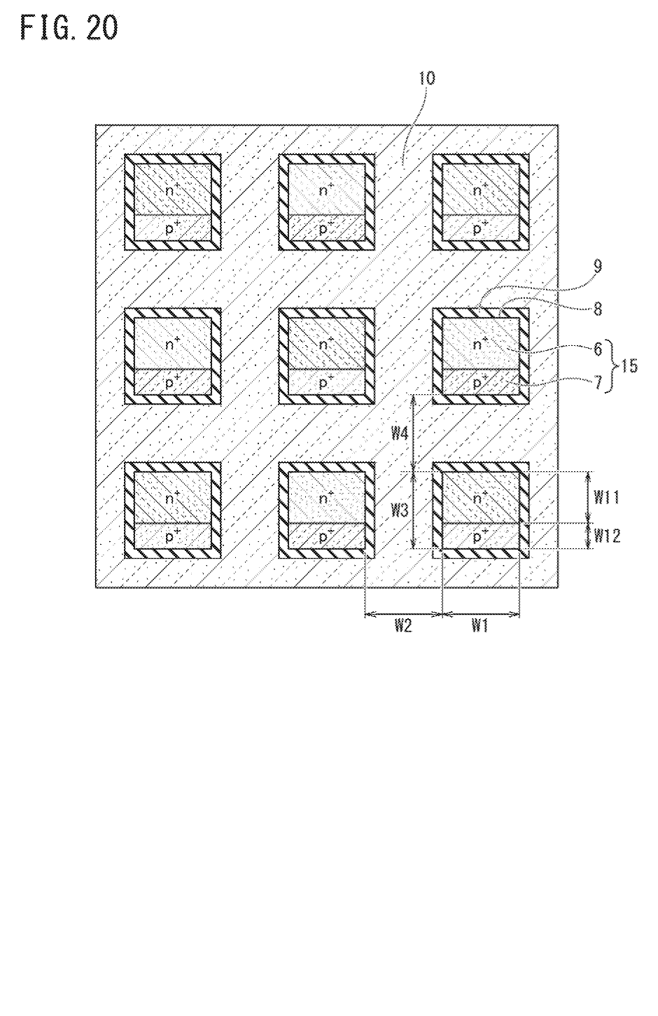

FIG. 20 illustrates a horizontal cross section of an insulated gate semiconductor device according to a twelfth embodiment, corresponding to the horizontal cross section of the insulated gate semiconductor device according to the first embodiment illustrated in FIG. 2. As illustrated in FIG. 20, the insulated gate semiconductor device according to the twelfth embodiment differs from the insulated gate semiconductor device according to the first embodiment illustrated in FIG. 2 in a structure of the respective mesa parts 15 arranged in a matrix form.

The insulated gate semiconductor device according to the twelfth embodiment includes the mesa parts 15 each having a rectangular, particularly square, planar pattern. The respective mesa parts 15 may have an oblong planar pattern defined such that the first direction (the right-left direction in FIG. 20) is a short-side direction, and the second direction (the upper-lower direction in FIG. 20) perpendicular to the first direction is a longitudinal direction.

The mesa parts 15 each include, in the planar pattern, the n⁺-type source region 6, and the p⁺-type base contact region 7 in contact with the source region 6 in the second direction (the upper-lower direction in FIG. 20). The width W11 of the source region 6 and the width W12 of the base contact region 7 in the second direction (the upper-lower direction in FIG. 20) may be either common to or different from each other.

The width W1 of the mesa parts 15 in the first direction (the right-left direction in FIG. 20) and the width W3 of the mesa parts 15 in the second direction (the upper-lower direction in FIG. 20) are each set to about 600 nanometers or smaller, and may be set to about 400 nanometers or smaller, may be set to about 200 nanometers or smaller, or may be set to about 100 nanometers or smaller, for example. The width W1 of the mesa parts 15 in the short-side direction may also be set in a range of about 50 nanometers or greater and 600 nanometers or smaller, may be set in a range of about 50 nanometers or greater and 400 nanometers or smaller, may be set in a range of about 50 nanometers or greater and 200 nanometers or smaller, or may be set in a range of about 50 nanometers or greater and 100 nanometers or smaller, for example.

Any of the four side surfaces orthogonal to the four sides of the rectangle of the respective mesa parts 15 in the planar pattern may be either an m-plane or an a-plane. For example, the side surfaces in contact with the two sides of the respective mesa parts 15 parallel to the upper-lower direction in FIG. 20 are each defined as an m-plane, and the side surfaces in contact with the two sides of the respective mesa parts 15 parallel to the right-left direction in FIG. 20 are each defined as an a-plane. This case uses an a-plane having a relatively high mobility for the side surface of the respective mesa parts 15 in contact with the source region 6 on the upper side in FIG. 20, and uses an a-plane having a relatively low mobility for the side surface of the respective mesa parts 15 in contact with the base contact region 7 on the lower side in FIG. 20. This configuration can use the m-plane and the a-plane with the relatively high mobility each as a channel, without use of the a-plane with the relatively low mobility as a channel, so as to reduce ON-resistance.

The width W1 of the respective mesa parts 15 in the first direction (the right-left direction in FIG. 20) and the width W11 of the source region 6 in the second direction (the upper-lower direction in FIG. 20) may be set such that the mobility of the m-plane, which is the side surface of the respective mesa parts 15 in contact with the source region 6 parallel to the upper-lower direction in FIG. 20, approximates to the mobility of the a-plane, which is the side surface of the respective mesa parts 15 in contact with the source region 6 on the upper side in FIG. 20. For example, the width W11 of the source region 6 may be set to be about 1.2 times or greater and 1.5 times or smaller as large as the width W1 of the respective mesa parts 15.

The other configurations of the insulated gate semiconductor device according to the twelfth embodiment are substantially the same as those of the insulated gate semiconductor device according to the first embodiment, and overlapping explanations are not repeated below.

The insulated gate semiconductor device according to the twelfth embodiment has the configuration as described above in which the mesa parts 15 are arranged in a matrix form, and the widths W1 and W3 of the rectangle of the respective mesa parts 15 in the planar pattern are each decreased to 600 nanometers or smaller. This configuration can ensure the FinFET effect on the side surfaces of the respective mesa parts 15, so as to reduce ON-resistance.

### OTHER EMBODIMENTS

As described above, the present disclosure has been described according to the first to twelfth embodiments, but it should not be understood that the description and drawings implementing a portion of this disclosure limit the present disclosure. Various alternative embodiments, examples, and operational techniques will be apparent to those skilled in the art from this disclosure.

For example, the respective insulated gate semiconductor devices according to the first to twelfth embodiments are illustrated above with the trench-gate vertical MOSFET, but the respective embodiments may be applied to a case of using an insulated gate bipolar transistor (IGBT) including a p⁺-type collector region, instead of the n⁺-type drain region 1 in the MOSFET. Further, the respective embodiments may also be applied to a case of using a reverse conductive IGBT (RC-IGBT) or a reverse blocking IGBT (RB-IGBT), instead of a single IGBT.

Further, the respective insulated gate semiconductor devices according to the first to twelfth embodiments are illustrated above with the case of including silicon carbide (SiC), but are not limited to this case. For example, the respective insulated gate semiconductor devices may include silicon (Si), or may include semiconductor (wide bandgap semiconductor) having a wider bandgap than Si, such as gallium nitride (GaN), gallium oxide (Ga₂O₃), diamond (C), and aluminum nitride (AlN).

In addition, the configurations disclosed in the first to twelfth embodiments can be combined together as appropriate within a range having no contradiction between the embodiments. For example, the matrix form does not necessarily entirely have the same pattern, but may have a structure with a plurality of regions having different patterns combined together. Further, a repeated pitch of the pattern may be changed, or a starting position of the repeated pattern may be shifted as appropriate. It should be understood that the present disclosure can include various embodiments not disclosed herein. The technical scope of the present disclosure is thus defined only by the subject matter according to the appended claims reasonably derived from the foregoing descriptions.

What is claimed is:

1. An insulated gate semiconductor device comprising:
a drift layer of a first conductivity-type;
a base region of a second conductivity-type provided on a top surface side of the drift layer;
a main region of the first conductivity-type provided on a top surface side of the base region; and
a gate electrode buried, with a gate insulating film interposed, in trenches dug downward from a top surface of the main region,
wherein a plurality of mesa parts interposed between the trenches adjacent to each other are arranged in a matrix form, and
a width of the respective mesa parts at least in one direction is set to 600 nanometers or smaller.

2. The insulated gate semiconductor device of claim 1, wherein the respective mesa parts have a planar pattern of a polygonal shape.

3. The insulated gate semiconductor device of claim 2, wherein any of side surfaces of the respective mesa parts is either an m-plane or an a-plane.

4. The insulated gate semiconductor device of claim 2, wherein the width of the respective mesa parts is narrower than a width of the respective trenches in the one direction.

5. The insulated gate semiconductor device of claim 2, wherein the respective mesa parts have a planar pattern of a rectangular shape.

6. The insulated gate semiconductor device of claim 5, wherein
the semiconductor device comprises a plurality of the main regions, and
the respective mesa parts include:
a base contact region of the second conductivity-type provided on the top surface side of the base region; and
two of the main regions arranged to interpose the base contact region so as to be in contact with each other.

7. The insulated gate semiconductor device of claim 5, wherein
the rectangular shape is an oblong,
a side surface in contact with a long side of the oblong is an m-plane, and
a side surface in contact with a short side of the oblong is an a-plane.

8. The insulated gate semiconductor device of claim 2, wherein the respective mesa parts have a planar pattern of a hexagonal shape.

9. The insulated gate semiconductor device of claim 8, wherein side surfaces in contact with sides of the hexagonal shape are each an m-plane.

10. The insulated gate semiconductor device of claim 8, wherein the respective mesa parts include:
a base contact region of the second conductivity-type provided on the top surface side of the base region; and
the main region arranged to surround the base contact region.

11. The insulated gate semiconductor device of claim 8, wherein:
the respective mesa parts include a first mesa part and a plurality of second mesa parts arranged to surround the first mesa part;
the first mesa part includes a base contact region of the second conductivity-type provided on the top surface side of the base region; and
the second mesa parts each include the main region.

12. The insulated gate semiconductor device of claim 1, wherein the respective mesa parts have a planar pattern of a circular or elliptic shape.

13. The insulated gate semiconductor device of claim 2, wherein the respective mesa parts have a planar pattern of an oblong.

14. The insulated gate semiconductor device of claim 13, wherein
the respective mesa parts include:
a base contact region of the second conductivity-type provided on the top surface side of the base region; and
the main region arranged in contact with the base contact region in a longitudinal direction of the oblong, and
the base contact regions of the mesa parts adjacent to each other are opposed to each other in the longitudinal direction and a short-side direction of the oblong.

15. The insulated gate semiconductor device of claim 13, wherein
the mesa parts include first mesa parts and second mesa parts,
the first mesa parts each include a base contact region of the second conductivity-type provided on the top surface side of the base region,
the second mesa parts each include the main region,
one of the first mesa parts and two of the second mesa parts are alternately and repeatedly arranged in a short-side direction of the oblong, and
the respective first mesa parts and the respective second mesa parts are repeatedly arranged in a longitudinal direction of the oblong.

16. The insulated gate semiconductor device of claim 13, wherein
the mesa parts include first mesa parts and second mesa parts,
the first mesa parts each include the main region,
the second mesa parts each include a base contact region of the second conductivity-type provided on the top surface side of the base region, and the main region arranged in contact with the base contact region in a longitudinal direction of the oblong,
the respective first mesa parts and the respective second mesa parts are repeatedly arranged in a short-side direction of the oblong, and
the main region of the respective second mesa parts is opposed to the main region of the respective first mesa parts in the longitudinal direction of the oblong.

17. The insulated gate semiconductor device of claim 13, wherein
the mesa parts include first mesa parts and second mesa parts,
the first mesa parts each include a base contact region of the second conductivity-type provided on the top surface side of the base region,
the second mesa parts each include the base contact region and the main region arranged in contact with the base contact region in a longitudinal direction of the oblong,
the respective first mesa parts and the respective second mesa parts are repeatedly arranged in a short-side direction of the oblong, and
the base contact region of the respective second mesa parts is opposed to the base contact region of the respective first mesa parts in the longitudinal direction of the oblong.

18. The insulated gate semiconductor device of claim 13, wherein
the mesa parts include first mesa parts and second mesa part,
the first mesa parts each include a base contact region of the second conductivity-type provided on the top surface side of the base region,
the second mesa parts each include the main region,
the plural first mesa parts are arranged in a short-side direction of the oblong, and
the plural second mesa parts are arranged to surround a circumference of the plural first mesa parts.

19. The insulated gate semiconductor device of claim 1, wherein the width of the respective mesa parts at least in the one direction is set to 400 nanometers or smaller.

20. The insulated gate semiconductor device of claim 1, wherein the width of the respective mesa parts at least in the one direction is set to 200 nanometers or smaller.
